(19) United States
(12) Patent Application Publication
(10) Pub. No.: US 2014/0014943 A1
(43) Pub. Date: Jan. 16, 2014

(54) AMORPHOUS PHASE YTTRIUM-DOPED INDIUM ZINC OXIDE THIN FILM TRANSISTORS AND METHOD FOR MAKING SAME

(71) Applicants: Chu-Chi TING, Minhsiung Township (TW); Hsieh-Ping CHANG, Minhsiung Township (TW)

(72) Inventors: Chu-Chi TING, Minhsiung Township (TW); Hsieh-Ping CHANG, Minhsiung Township (TW)

(73) Assignee: NATIONAL CHUNG CHENG UNIVERSITY, Minhsiung Township (TW)

(21) Appl. No.: 13/549,844

(22) Filed: Jul. 16, 2012

(51) Int. Cl. H01L 29/24; H01L 29/786; H01L 21/336; H01L 21/36

(52) U.S. Cl. 257/43; 438/104; 257/E29.101; 257/E29.273; 257/E21.411; 257/E21.461

(57) ABSTRACT

Sol-gel-processed thin-film transistors (TFTs) with amorphours Y—In—Zn—O (YIZO) as an active layer are fabricated with various mole ratios of Y, which indicates that Y³⁺ could play the role of carrier suppressor in InZnO (IZO) systems and reduce off current of YIZO-TFT and its channel mobility, threshold voltage, subthreshold swing voltage, and on/off ratio.

### BACKGROUND OF THE INVENTION

1. Field of the Invention

The present invention relates to thin film transistors and method for making same, and particularly to amorphous phase yttrium-doped indium zinc oxide thin film transistors and method for making same.

2. Description of Related Art

The working principle and properties of the thin film transistor (TFT) are related to the structures and the device operation of the TFT. According to the structure, the TFT can be classified into top gate and bottom gate based on the position of the gate electrode while it also can be classified into top contact and bottom contact based on the position of source electrode and drain electrode, and thus the TFT has four different structures, as shown in Rolland, A. et al. J. Electrochem. Soc. 140, 3679-3683 (1993). The channel length (L) and the channel width (W) of the channel of the active layer that is between the source and the drain are important parameters.

As mentioned in Kagan, C. R. et al. (eds) Thin Film Transistors (Marcel Dekker, New York, 2003), in terms of device operation of the TFT, two characteristic curves can be obtained by applying different biases on the three terminals, which are the gate, the source and the drain. One of the two characteristic curves is output characteristic curve and the other is transfer characteristic curve. The output characteristic curve is obtained by applying a constant gate-to-source voltage (V_{GS}) and measuring the value of drain-to-source current (I_{DS}) by changing the value of drain-to-source voltage (V_{DS}), and the transfer characteristic curve is obtained by applying a constant V_{DS} and measuring the value of I_{DS} by changing the value of V_{GS}. The transfer characteristic curve of the TFT can be divided into three operating regions by the output characteristic curve, and the three operating regions are linear region, triode region and saturation region respectively.

When V_{DS}<(V_{GS}−VT) occurs, the linear region or the triode region mentioned above is conducting and forms a channel at the active layer/dielectric layer interface. The TFT under this situation is like a voltage-controlled resistor and the drain current is

$${I}_{D} = μ {C}_{ins} \frac{W}{L} [ ( {V}_{GS} - {V}_{T} ) {V}_{DS} - \frac{{V}_{DS}^{2}}{2} ] … ( {V}_{DS} \leq {V}_{GS} - {V}_{T} ) \qquad ( Eq . 2 \text{-} 1 )$$

Where μ is carrier mobility, W is the width of the channel of the TFT, L is the length of the channel of the TFT, and Cₒₓ is the capacitance per unit area of the gate oxide. In this region, the drain current is linearly related to drain-source voltage and this region is thus named a linear region.

A saturation region occurs when V_{DS}>(V_{GS}−V_{T}), and the TFT in this situation is conducting and forms a channel to let current pass through. However, as the drain voltage increases and exceeds the gate voltage, the inversion layer charge that is near the drain becomes zero, and thus the channel disappears, which is called pinch-off. In this situation, carriers leave the source and pass through the channel, and once the carriers arrive at the pinch-off point, they will be injected into the space charge region around the drain and then be driven to the drain by electric field. Under this circumstance, the current passing through the TFT is not related to the V_{DS} but only related to the gate voltage, as shown in equation 2-2.

$${I}_{D} = \frac{1}{2} {C}_{ins} {\frac{W}{L} [ {V}_{GS} - {V}_{T} ]}^{2} … ( {V}_{DS} > {V}_{GS} - {V}_{T} ) \qquad ( Eq . 2 \text{-} 2 )$$

The TFT parameter extraction is mainly about transconductance (gₘ), field-effect mobility (μ_{FE}), saturation mobility (μₛₐₜ), I_{DS} on/off ratio (I_{on/off}), subthreshold swing (S.S.), N_{SS}^{max}, and threshold voltage (V_{T}). Among them, in light of transconductance, the TFT is in the linear region, and the equation 2-1 can be simplified as equation 2-3 when V_{DS} is low (V_{DS}<<V_{GS}−V_{T}).

$${I}_{D} = μ {C}_{ins} \frac{W}{L} {V}_{DS} [ {V}_{GS} - {V}_{T} ] \qquad ( Eq . 2 \text{-} 3 )$$

The transconductance is defined as a constant value of the variation of the source current to the variation of the V_{GS}, as shown in equation 2-4.

$${g}_{m} = \frac{\partial {I}_{D}}{\partial {V}_{GS}} {\vert}_{{V}_{DS}} = constant \qquad ( Eq . 2 \text{-} 4 )$$

Combining equation 2-4 and 2-5, the transconductance (gₘ) can also be shown as

$${g}_{m} = \frac{W}{L} {μ}_{FE} {C}_{ox} {V}_{DS} \qquad ( Eq . 2 \text{-} 5 )$$

When V_{DS} is low (V_{DS}<<V_{GS}−V_{T}), field-effect mobility is defined by equation 2-6 from transposing equation 2-5.

$${μ}_{FE} = \frac{{Lg}_{m}}{W {C}_{ox} {V}_{DS}} \qquad ( Eq . 2 \text{-} 6 )$$

For saturation mobility, the TFT is in the saturation region when V_{DS}>V_{GS}−V_{T}, and the saturation current (I_{D,sat}) is obtained by taking the square root of each side of equation 2-2:

$$\sqrt{{I}_{D , sat}} = \sqrt{\frac{1}{2} μ {C}_{ins} \frac{W}{L}} [ {V}_{GS} - {V}_{T} ] \qquad ( Eq . 2 \text{-} 7 )$$

Equation 2-7 is linearly related to V_{GS}. Differentiate equation 2-7 over V_{GS} and derive equation 2-8.

$$\frac{d \sqrt{{I}_{D , sat}}}{d {V}_{GS}} = \sqrt{\frac{1}{2} μ {C}_{ins} \frac{W}{L}} \qquad ( Eq . 2 \text{-} 8 )$$

Take the square root of each side of equation 2-8 and transpose terms, the saturation mobility (μₛₐₜ) is defined as

$${μ}_{sat} ( {V}_{GS} ) = \frac{{( \frac{d \sqrt{{I}_{D , sat}}}{d {V}_{GS}} )}^{2}}{\frac{1}{2} {C}_{ins} \frac{W}{L}} \qquad ( Eq . 2 \text{-} 9 )$$

The I_{DS} on/off ratio (I_{on/off}) is derived from the transfer characteristic curve by reading out the variation of I_{DS} and sweeping V_{GS} from negative to positive voltages under a fixed V_{DS}. Based on the I_{DS}−V_{GS} data, I_{DS} on/off ratio (I_{on/off}) is defined as the ratio of the maximum value to the minimum value of the output source-drain current of the TFT. The parameter is used to indicate the on/off property of the TFT. Currently the on/off ratio of present commercial TFT must be larger than 10⁶.

The value of the subthreshold swing (S.S.) of the TFT is an important parameter. The smaller the value of the subthreshold swing, the smaller the voltage required for the TFT to turn from off-state to on-state. In the subthreshold range, the subthreshold swing (S) is defined as the variation of the V_{GS} required to force the output I_{DS} to increase to ten times. The value of S is the maximum slope of the transfer characteristic curve, as mentioned in Kagan et al. (eds), Thin Film Transistors (Marcel Dekker, New York, 2003). The equation of S is

$$S = \frac{d {V}_{G}}{d ( log {I}_{D} )} \qquad ( Eq . 2 \text{-} 10 )$$

As mentioned in Kagan et al. (eds), Thin Film Transistors (Marcel Dekker, New York, 2003), the maximum defect density of the active layer/dielectric layer interface can be calculated from S by equation 2-11.

$${N}_{SS}^{max} = ( \frac{S log ( e )}{kT / q} - 1 ) \frac{{C}_{i}}{q} \qquad ( Eq . 2 \text{-} 11 )$$

According to the data measured by the I_{DS}−V_{G} characteristics of the transfer characteristic curve, threshold voltage (V_{T}) can be calculated from equation 2-4 when V_{DS}=0.1V and when V_{DS}=V_{GS},V_{T} can be calculated from equation 2-7.

Transparent amorphous oxide semiconductors (TAOSs) are used as active layers of TFTs. Depositing the TAOS on the flexible substrates to manufacture flexible transparent TFTs (TTFTs) is a technique of applying inorganic materials to flexible substrates. The TAOS have special bonding structure and still have large Hall mobility (μ_{Hall}) about 10-50 cm²/Vs.

The carrier mobility of TFT should be larger than 4 cm²/Vs when using the TFT to drive the active matrix organic light-emitting diode (OLED) pixel. The carrier mobility of TFT should be larger than 2 cm²/Vs when using the TFT to drive the active matrix liquid crystal display (AMLCD) of large-sized panels, which are more than 90 inches. The TAOS-TFT meets the needs mentioned above and is anticipated to replace amorphous silicon TFT (a-Si TFT) and low temperature poly-silicon (LTPS-TFT) in the future, as mentioned in Nomura, K. et al. Nature 432, 488-492 (2004) and Kamiya, T. et al. NPG Asia Mater. 2(1), 15-22 (2010).

In 2004, H. Hosono et al. published a publication (Nomura, K. et al. Nature 432, 488-492 (2004) of Nature) related to the amorphous oxide semiconductor (AOS), which mentioned the μ_{Hall} of the single-crystal-silicon is about 200 cm²/Vs and the μ_{Hall} of the hydrogen-dopped amorphous silicon (a-Si:H) is about 1 cm²/Vs. The difference between the μ_{Hall} of the single-crystal-silicon and the a-Si:H can be attributed to the type of chemical bonding. Silicon forms bonds through sp³ hybridization wherein the bonds are directional. Carriers in the amorphous silicon structures are hard to move due to many complicated non-bonding sp³ hybrid orbitals, thus resulting in the low μ_{Hall} of a-Si:H. However, AOS contains transition metal cation, of which the electron configuration is (n−1)d¹⁰ ns⁰, n≧4, and thus AOS forms transfer path for carriers by overlapping of the s orbitals of the adjacent transition metals. As a result, even being non-crystalline, the AOS still has a larger μ_{Hall}.

Besides, in 2011, H. Sirringhaus et al. published a publication in Nature Materials (Banger, K. K. et al. Nature materials 10, 45-50 (2011)), which mentioned that they utilized solution processing to prepare IZO of different ratios, and when there is an excess amount of indium or zinc, the crystalline phase exists and the carrier mobility of the TFT is low.

As mentioned in Kamiya, T. et al. NPG Asia Mater 2(1), 15-22 (2010), advantages of AOS TFTs include, for example, applicabilities to flat-panel displays and large scale integrated circuit. Compared to the μₛₐₜ of a-Si:H TFTs, the μₛₐₜ of AOS TFTs is ten times lager. The other advantages are described as follows:
1. AOS TFTs can be fabricated by low-temperature processing techniques such as pulsed laser deposition (PLD) and DC sputtering, and can be applied to flexible substrates.
2. The range of the processing temperature is wide according to the different chemical compositions of the materials.
3. AOSs has large μ_{Hall} due to the chemical composition thereof, and thus AOS TFTs have large electron mobility.
4. Compared to the covalent bond of Si, the special chemical bonds between metals and oxygen ions of AOS result in low defect density, and thus AOS TFTs have low operating voltage.
5. AOS TFTs are applicable to many dielectric materials.
6. The structure of AOS TFTs is simple and can be easily fabricated.

With TFTs comprising quaternary compound based on indium zinc oxide system, the indium zinc oxide system is doped with other elements and the active layer of the TFT is fabricated by the sol-gel process, wherein the dopant elements suppress the formation of oxygen vacancies, and thus the dopant elements suppress the active layer and further improve the trap density, lower the subthreshold swing (S,S), reduce the off current and result in shift of V_{T} toward more positive values.

In 2010, as published in Kim, G. H. et al. Appl. Phys. Lett. 96, 163506 (2010), Kim, G. H. et al. disclosed that they used the sol-gel process to fabricate the TFT comprising Mg-doped In—Zn—O (Mg—In—Zn—O, MIZO) and compared the standard electrode potential (SEP, E°) of magnesium, zinc and indium, wherein the E° of magnesium is −2.37 V, the E° of zinc is −0.76 V, and the E° of indium is −0.34 V. Magnesium has a lower standard oxidation reduction potential, and thus magnesium is easily oxidized, is capable of binding oxygen, reduces formation of oxygen vacancies, reduces electron carrier concentration, and increases electrical resistivity. Moreover, the lower standard oxidation-reduction potential of magnesium can control the optical band gap and grain size of MIZO. Also mentioned in the publication is that the best properties of transistors are: a ratio of [Mg]/([In]+[Zn])=0.2, the TFT exhibiting the I_{on/off} of about 5×10⁸, the field-effect mobility of 2.7 cm²/Vₛ, the turn-on voltage of −3 V and the subthreshold swing of 0.20 V/decade.

In 2010, as published in Kim, D. N. et al. Appl. Phys. Lett. 97, 192105 (2010), D. N. Kim et al. disclosed that they used solution processing to prepare the active layer of TFT comprising lanthanum-doped indium zinc oxide (La—In—Zn—O) wherein the indium zinc oxide-based system is doped with small amount of lanthanum. The electronegativities of lanthanum, indium, zinc and oxygen are 1.1, 1.8, 1.7 and 3.5 respectively. Compared to the electronegativity difference between indium and oxygen or zinc and oxygen, the electronegativity difference between lanthanum and oxygen is larger, and thus a stronger bond is formed between lanthanum and oxygen, reducing the formation of oxygen vacancies, lowering electron carrier concentration, and lowering the off current. This publication also mentioned that the best properties of transistors are: a ratio of La:In:Zn=0.5:5:5, the TFT exhibiting the Ion/off of about 10⁶, the field-effect mobility of 2.64 cm²/Vs, the V_{T} of 7.86 V and the subthreshold swing of 0.60 V/decade.

In 2010, as published in Jeong, W. H. et al. Appl. Phys. Lett. 96, 093503 (2010), W. H. Jeong et al. disclosed that they used the sol-gel process to fabricate the active layer of TFT comprising hafnium-doped indium zinc oxide (HIZO) wherein the indium zinc oxide-based system is doped with hafnium. Compared with the HIZO TFT with GaInZnO (GIZO) TFT, the authors mentioned that hafnium has lower SEP, and thus hafnium has a stronger affinity for oxygen and suppresses carriers. The result of this publication showed that lower defect density results in steep subthreshold swing.

In 2010, as published in Choi, Y. et al. Appl. Phys. Lett. 97, 162102 (2010), Y. Choi et al. disclosed that they used the sol-gel process to fabricate the TFT comprising scandium-doped indium zinc oxide (Sc—In—Zn—O, SIZO), wherein scandium could effectively control the formation of oxygen vacancies and suppress electron carrier concentration. As the doping ratio of scandium increases, scandium can lower off current (I_{off}), increase visible light transmission and result in shift of V_{T} toward more positive values. This publication showed a result of effectively binding oxygen by using scandium and indium, by the lower SEP of zinc and by the large electronegativity difference between scandium and oxide. This publication also mentioned that the best properties of transistors are: indium zinc oxide system doped with 14% scandium, the TFT exhibiting the I_{on/off} of about 8.02×10⁶, the field-effect mobility of 2.06 cm²/Vs, the V_{T} of 4.31 V and the subthreshold swing of 0.93 V/decade.

However, according to the prior arts mentioned above, many problems remain unsolved: effectively suppressing carrier concentration, shift of V_{T} toward positive voltage, lowering off current, increasing optical band gap (Eₒₚₜ) and improving visible light transmission.

Besides, although IGZO materials are already known from the prior arts, the market still has a strong demand for new TAOS material.

To overcome the shortcomings, the present invention provides an amorphous phase yttrium-doped indium zinc oxide thin film transistors and method for making same to mitigate or obviate the aforementioned problems.

### SUMMARY OF THE INVENTION

The present invention fabricates TAOS by non-vacuum solution process in order to obtain an accurate doping ratio of elements and reduce cost. The present invention applies TAOS to TFTs, and the active layer of TFTs of the invention is made by said TAOS. To provide new TAOS material, the TAOS of the invention has an indium zinc oxide-based system wherein the molarity of indium and the molarity of zinc are the same, namely, the mole ratio of indium to zinc is 1:1 and the ratio is based on amorphous phase. According to the electronegativity and the standard electrode potential (SEP), the present invention uses the yttrium as the dopant in the IZO system to suppress carrier concentration and to fabricate yttrium-doped indium zinc oxide thin film transistors (YIZO TFTs).

Moreover, in order to solve the aforementioned problems of the conventional TFTs, the present invention achieves the effects as follows by utilizing doping with yttrium:

1. The Standard electrode potentials (SEP) of indium, zinc and yttrium are −0.34, −0.76 V and −2.65 V respectively, and compared to zinc or yttrium, yttrium has a smaller SEP, which means that the element is easily oxidized to form a steady state and suppresses the formation of oxygen vacancies.

2. The electronegativities of indium, zinc, yttrium and oxygen are 1.78, 1.65, 1.22 and 3.44 respectively. The electronegativity difference between yttrium and oxygen is 2.22, which is larger than the electronegativity difference between indium and oxygen (1.66) and is larger than the electronegativity difference between zinc and oxygen (1.79), and thus yttrium and oxygen can form a stronger bond and suppress the formation of oxygen vacancies.

Other objectives, advantages and novel features of the invention will become more apparent from the following detailed description when taken in conjunction with the accompanying drawings.

### BRIEF DESCRIPTION OF THE DRAWINGS

FIG. 1 is a schematic diagram of measuring TFT;

FIG. 2 is a schematic diagram of a method measuring sheet resistance of a semiconductor material by Van der Pauw method;

FIG. 3 is a schematic diagram of a method measuring Hall Effect of a semiconductor material by Van der Pauw method;

FIG. 4 is a flow diagram of making TFTs;

FIG. 5 is a schematic diagram of the device structure with the active layer undefined;

FIG. 6 is a schematic diagram of the device structure with the defined active layer;

FIG. 7 is a diagram of the output characteristic curve (I_{DS}−V_{DS}) of TFT with the active layer undefined;

FIG. 8 is a diagram of the output characteristic curve a V_{DS}−V_{DS}) of TFT with the defined active layer;

FIG. 9 is a diagram of the transfer characteristic curve (I_{DS}−V_{DS}) of TFT with the active layer undefined;

FIG. 10 is a diagram of the transfer characteristic curve (I_{DS}−V_{DS}) of TFT with the defined active layer;

FIG. 11 is a diagram of the output characteristic curve (V_{DS}−I_{DS}) of TFT when the doping ratio of yttrium was 0%, i.e. IZO, and the IZO had been sintered for 1 hour at 500° C. under atmosphere;

FIG. 12 is a diagram of the output characteristic curve (V_{DS}−I_{DS}) of TFT when the doping ratio of yttrium was 6% and the YIZO had been sintered for 1 hour at 500° C. under atmosphere;

FIG. 13 is a diagram of the output characteristic curve (V_{DS}−I_{DS}) of TFT when the doping ratio of yttrium was 8% and the YIZO had been sintered for 1 hour at 500° C. under atmosphere;

FIG. 14 is a diagram of the output characteristic curve (V_{DS}−I_{DS}) of TFT when the doping ratio of yttrium was 12% and the YIZO had been sintered for 1 hour at 500° C. under atmosphere;

FIG. 15 is a diagram of the output characteristic curve (V_{DS}−I_{DS}) of TFT when the doping ratio of yttrium was 14% and the YIZO had been sintered for 1 hour at 500° C. under atmosphere;

FIG. 16 is a diagram of the output characteristic curve (V_{DS}−I_{DS}) of TFT when the doping ratio of yttrium was 20% and the YIZO had been sintered for 1 hour at 500° C. under atmosphere;

FIG. 17 is a diagram of the transfer characteristic curve (I_{DS}−V_{GS}) of TFTs with different doping ratios of yttrium by applying a constant V_{DS} of 1.1 V and sweeping V_{G} from −30 to 30 V, wherein the YIZO had been sintered for 1 hour at 500° C.;

FIG. 18 is a diagram of the transfer characteristic curve (I_{DS}−V_{GS}) of TFTs with different doping ratios of yttrium by applying a constant V_{DS} of 2.1 V and sweeping V_{G} from −30 to 30 V, wherein the YIZO had been sintered for 1 hour at 500° C.;

FIG. 19 is a diagram of the transfer characteristic curve (I_{DS}−V_{GS}) of TFTs with different doping ratios of yttrium by applying a constant V_{DS} of 5.1 V and sweeping V_{G} from −30 to 30 V, wherein the YIZO had been sintered for 1 hour at 500° C.;

FIG. 20 is a diagram of the transfer characteristic curve (I_{DS}−V_{GS}) of TFTs with different doping ratios of yttrium by applying a constant V_{DS} of 10 V and sweeping V_{G} from −30 to 30 V, wherein the YIZO had been sintered for 1 hour at 500° C.;

FIG. 21 is a diagram of the transfer characteristic curve (I_{DS}−V_{GS}) of TFTs with different doping ratios of yttrium by applying a constant V_{DS} of 20 V and sweeping V_{G} from −30 to 30 V, wherein the YIZO had been sintered for 1 hour at 500° C.;

FIG. 22 is a GIXRD diagram of YIZO thin films with different doping concentrations of yttrium, wherein SiO₂ substrates of an 80 nm thickness were deposited with amorphous YIZO thin films sintered at 500° C. with different doping concentrations of yttrium wherein the different doping concentrations of yttrium were 0%, Y 6%, Y 12%, Y 20% respectively and each SiO₂ substrates was of an 80 nm thickness;

FIG. 23 is a diagram of electrical characteristics of thin films with different doping concentrations of yttrium (Y=0, 5, 10, 14, 20%);

FIG. 24 is an AFM diagram of a SiO₂ substrate of an 80 nm thickness deposited with an IZO thin film, i.e., the doping concentration of yttrium of YIZO thin film was 0%, and the SiO₂ substrate with the IZO thin film was sintered at 500° C.;

FIG. 25 is an AFM diagram of a SiO₂ substrate of an 80 nm thickness sintered at 500° C. and deposited with a YIZO thin film with an 8% doping concentration of yttrium;

FIG. 26 is an AFM diagram of a SiO₂ substrate of an 80 nm thickness sintered at 500° C. and deposited with a YIZO thin film with a 14% doping concentration of yttrium;

FIG. 27 is an AFM diagram of a SiO₂ substrate of an 80 nm thickness sintered at 500° C. and deposited with a YIZO thin film with a 20% doping concentration of yttrium;

FIG. 28 is a trend plot of surface roughness of YIZO with different doping concentrations of yttrium and the measuring range is 5 um×5 um;

FIG. 29 is a diagram of measurements of transmissions of YIZO thin films with different doping concentrations of yttrium and the YIZO thin films were deposited on glass substrates sintered at 500° C.;

FIG. 30 is a diagram of measurements of transmissions of YIZO thin films with different doping concentrations of yttrium and the YIZO thin films were deposited on glass substrates sintered at 500° C., wherein the measurement was performed by using a blank substrate and Tauc's equation to calculate the optical band gap;

FIG. 31 is an XPS spectrum of different doping concentrations of yttrium (In 3d5/2);

FIG. 32 is an XPS spectrum of different doping concentrations of yttrium (Zn 3p3/2);

FIG. 33 is an XPS spectrum of different doping concentrations of yttrium (Y 3d);

FIG. 34 is an XPS spectrum of different doping concentrations of yttrium (O 1s);

FIG. 35 is O 1s XPS peak of IZO (Y=0%);

FIG. 36 is O 1s XPS peak of YIZO (Y=12%);

FIG. 37 is O 1s XPS peak of YIZO (Y=20%);

### DETAILED DESCRIPTION OF PREFERRED EMBODIMENT

For a better understanding about the technical features of the present invention and its effect, and for implements in accordance with the disclosures of the specification, preferred embodiment, details and figures are further shown as follows:

### First Embodiment

This is an embodiment illustrative of the equipments, instruments, materials and methods of use involved in the embodiments of the present invention.

1. Processing Equipment: Spin Coater

The spin coater was from Professor Chu-Chi Ting's lab at National Chung Cheng University and the spin coater was placed in a class-100 clean glovebox. A clean syringe and a 0.20 um syringe filter were used to drop precursor on a substrate. The spin coating process is divided into two stages with two different spin-coating rate. During the first stage, solution was coated on the substrate evenly. During the second stage, the coating thickness of the coating layer was then controlled.

2. Processing Equipment: Tube Furnace

The tube furnace for sintering in the illustrative embodiments of the present invention was from Professor Chu-Chi Ting's lab at National Chung Cheng University that was purchased from Chitun Industry Corporation in Changhua County. The organic carbon chain in the precursor obtained from the sol-gel process would break and evaporate after being sintered at high temperature, and thus the precursor became inorganic material. The quartz glass tube in the illustrative embodiments of the present invention was from Professor Ting, Chu-Chi's lab in National Chung Cheng University and was used with a semicircle boat and a stepping motor to send the sample into and out of the tube furnace.

3. Processing Equipment: Evaporator

Professor Chia-Chen Hsu's lab at National Chung Cheng University provided the evaporator. The structure of the evaporator included a vacuum chamber, a mechanical pump, a turbo pump and a film thickness monitoring, wherein the film thickness monitoring was a quartz-crystal microbalance. The sequence of operating procedure of the evaporator was as follows: turning on the evaporator, warming-up the evaporator, venting on and putting in the sample, roughly vacuuming to a pressure of 6×10⁻³ torr, increasing spin speed to vacuum to a pressure of 6×10⁻⁶ torr, evaporating metal, decreasing spin speed, venting on and taking out the sample, roughly vacuuming to a pressure of 6×10⁻³ torr to maintain the chamber in a vacuumed state, and turning off the evaporator.

The principle of an evaporator is to use a large current to pass through a tungsten boat with an aluminum ingot and make the tungsten boat produce high temperature, and then the aluminum ingot on the tungsten boat will melt when reaching the melting temperature of above 660° C., followed by the evaporating of the metal on the sample. During the evaporation process, the vacuum value is kept under 6×10⁻⁶ Ton to avoid oxidization of aluminum, which will result in increasing the resistance of the metal and affecting the characteristics of the devices. Moreover, the principle of using quartz-crystal microbalance as film thickness monitoring to monitor the evaporation speed is based on the piezoelectric effect of quartz crystals. When the quartz crystal resonator provides resonance, it will generate voltage and amplify the generated voltage. A measurement of coating thickness is obtained after conversion, wherein the conversion should set the density of aluminum of 2.7 g/cm³ and acoustic impedance of 8.19×105 gm/cm² sec.

4. Processing Equipment: Mask Aligner

The UV mask aligner was from Professor Wen-Hsin Hsieh's lab of the Department of Mechanical Engineering at National Chung Cheng University that was purchased from M&R Nano Technology Corporation and the product type was AG500-4N-D-SM-H. The mercury lamp of the UV mask aligner provided parallel light and utilized a shutter with an exposure counter function. The wavelength of the mask aligner was 365 nm.

5. Electrical Characteristics Measurement Equipment: Electrical Characteristics Measurement Equipment of TFT

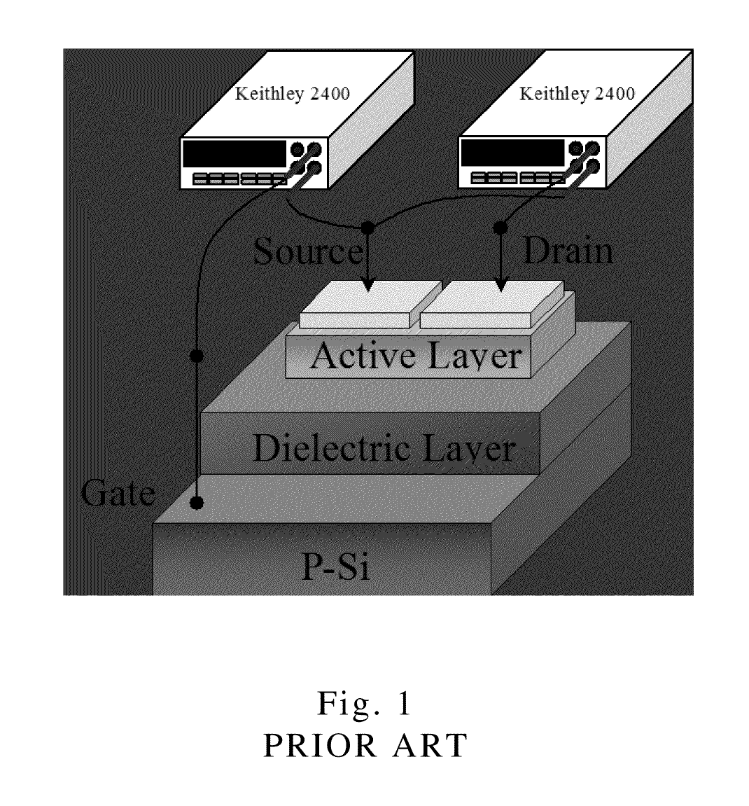

Professor Chu-Chi Ting's lab at National Chung Cheng University provided a pair of GPIB-USB and IEEE 488 transmission lines that were connected to two Keithley 2400 source meters and a computer, and obtained measurements and collected data by Lab Tracer free software. Other equipments included a carrier measurement (including a probe station, a probe tip, and a spring probe), a shielding box and the like. A circuit composed of TFT and the two Keithley 2400 source meters for measuring the TFT are shown in FIG. 1. The measurement items included:

1. The Setting for Measuring Output Characteristic Curve (I_{DS}−V_{DS} Curve)

(1) The step voltage of the gate was swept from −30V to 30 V.

(2) The sweep voltage of the source/drain was swept from 0V to 30 V.

2. The Setting of Measuring Transfer Characteristic Curve (I_{DS}−V_{GS} Curve)

(1) The sweep voltage of the gate was swept from −30V to 30 V.

(2) The step voltage of the source/drain was 0.1, 1.1, 2.1, 5, 10, 20 and 30 V.

From the data derived from transfer characteristic curve (I_{DS}−V_{GS} curve), V_{T}, SS, linear region, saturation mobility, maximum defect of interface and the like can be calculated.

6. Electrical Characteristics Measurement Equipment: Hall Measurement

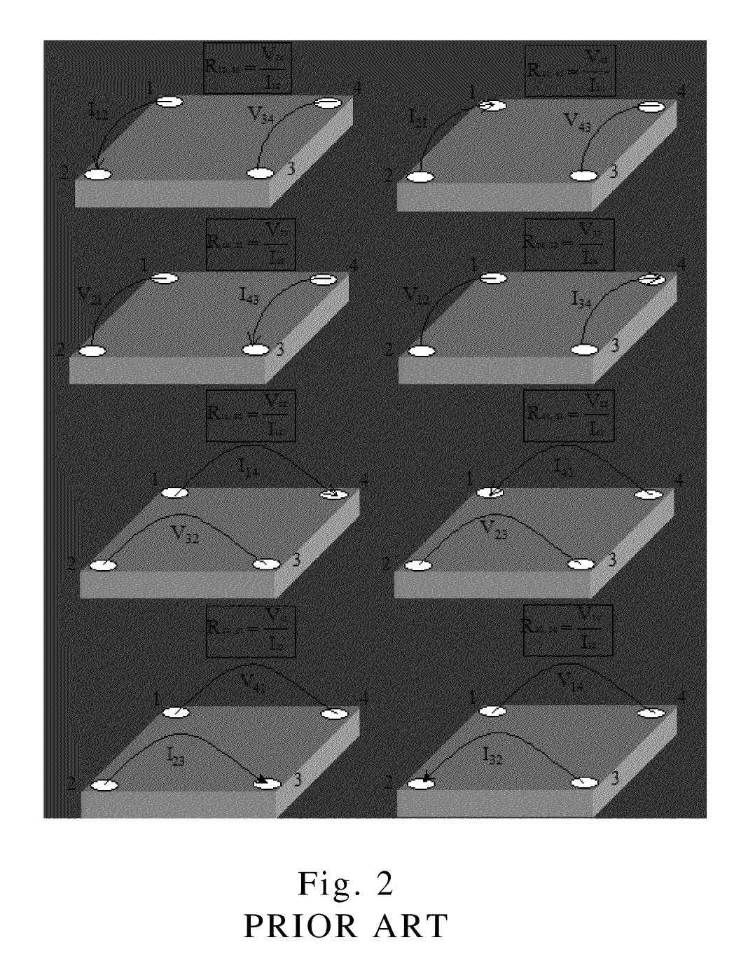

After Edwin Hall discovered the Hall Effect in 1879, Van der Pauw published a paper in Philips Technical Review in 1958 disclosing the measurements of resistivity, carrier concentration, and Hall mobility (μ_{Hall}) of the thin-film materials. An instrument set up by Van der Pauw method to measure Hall effect in the illustrative embodiments of the present invention was from Professor Chu-Chi Ting's lab in National Chung Cheng University wherein the instrument was composed of a small range and uniform magnetic field of two neodymium magnets four three-dimensional and adjustable probe stations and probe tips, a spring probe, a Keithley 2400, and a switch, wherein the central magnetic field of the two neodymium magnets was 0.55 Tesla. As mentioned in Van der Pauw, L. J. Philips Res. Repts. 13, 1-9 (1958), the Van der Pauw method is used to measure the resistivity. With reference to FIG. 2, eight data including R_{12,34}, R_{21,43}, R_{43,12}, R_{34,21}, R_{43,12}, R_{34,21}, R_{14,23} and R_{41,32} are obtained by 4-point probe. The parallel resistance is R_{A}(R_{14,23}+R_{41,32}+R_{23,41}+R_{32,14})/4, and the vertical resistance is R_{B}=(R_{43,12}+R_{34,21}+R_{14,23}+R_{41,32})/4. Moreover, the R_{A} and R_{B} should satisfy equation 3-1.

exp(−πRA/Rs)+exp(−πRB/Rs)=1 (Eq. 3-1)

The equation of resistivity is

$$ρ = {R}_{s} t = \frac{π}{ln ( 2 )} t \frac{( {R}_{A} + {R}_{B} )}{2} f \qquad ( Eq . 3 \text{-} 2 )$$

Where t is the thickness of material, f is a correction factor to correct the equation while the material is in an arbitrary shape. The equation of f is

$$f \approx 1 - {( \frac{{R}_{A} - {R}_{B}}{{R}_{A} + {R}_{B}} )}^{2} \frac{ln ( 2 )}{2} - {( \frac{{R}_{A} - {R}_{B}}{{R}_{A} + {R}_{B}} )}^{4} \{ \frac{{( ln 2 )}^{2}}{4} - \frac{{( ln 2 )}^{3}}{12} \} \qquad ( Eq . 3 \text{-} 3 )$$

Van der Pauw method and two additional neodymium magnets are used to measure Hall Effect, wherein a small range and uniform magnetic field between the two neodymium magnets is 0.5 Tesla. The theory is based on the charges experiencing a Lorentz Force and the equation is

\vec{F}=q\vec{V}×\vec{B} (Eq. 3-4)

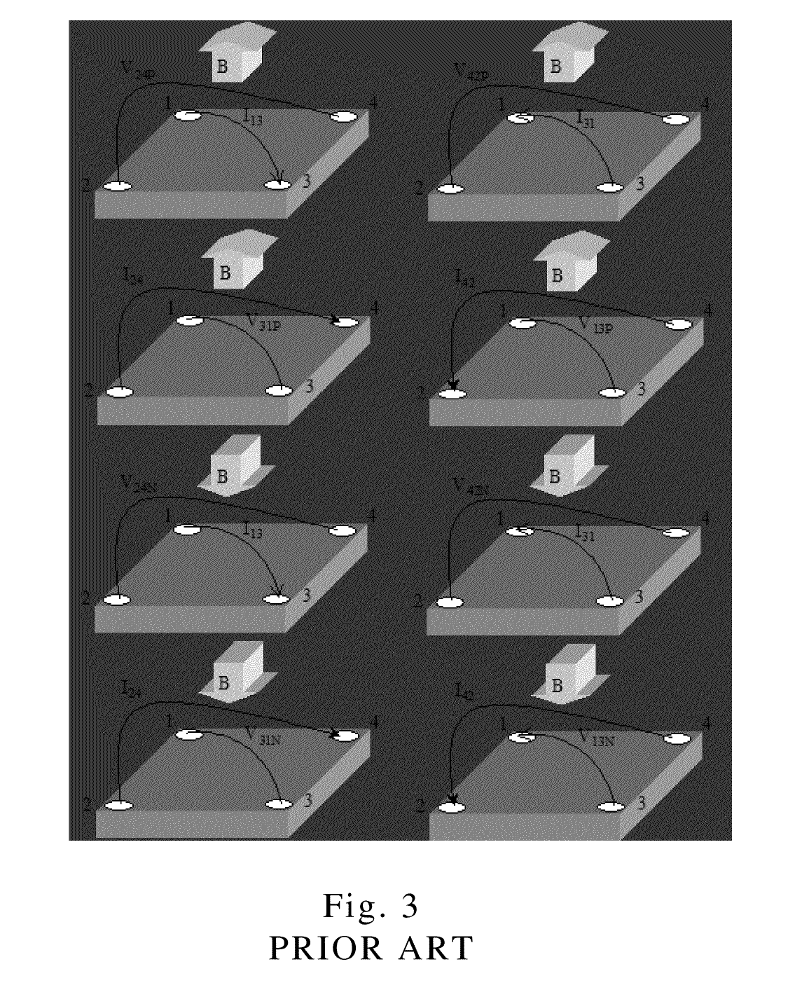

The measurement method is shown in FIG. 3. Eight data including V_{24P}, V_{42P}, V_{13P}, V_{31P}, V_{24N}, V_{42N}, V_{13N}, V_{31N} are obtained by 4-point probe. The Hall voltage (V_{Hall}) is calculated by

V_{Hall}=(V_{24P}+V_{42P}+V_{13P}+V_{31P})−(V_{24N}+V_{42N}+V_{13N}+V_{31N}) (Eq. 3-5)

V_{Hall} is substituted into equation 3-6 to get sheet concentration (nₛ) and the unit is cm⁻².

$${n}_{s} = \frac{8 \times {10}^{- 8} IB}{q \vert \sum {V}_{Hall} \vert} \qquad ( Eq . 3 \text{-} 6 )$$

Where I is an output constant current, B is a magnetic field strength of 0.55 Tesla, q is 1.602×10⁻¹⁹ C unit of charge. The carrier concentration (ne) is calculated by

ne=ns/d (Eq. 3-7)

The equation to calculate the Hall mobility is

$${μ}_{Hall} = \frac{1}{{qn}_{s} {R}_{s}} \qquad ( Eq . 3 \text{-} 8 )$$

7. Optical Characteristics Measurement Equipment: UV-Visible Spectrophotometer

The working principle of spectrophotometer is based on using visible light and UV lamp as light source and the light source is adjusted through a filter, after focusing, the light source passes though a monochromator and selects wavelength through the slit, thus resulting in a light source with a single and specified wavelength. The light source is then transmitted through the test sample and finally transmitted through photomultiplier to transfer spectral information into electric signals.

The single beam UV-Visible spectrophotometer (Agilent 8453) used in the present invention was from the lab of Professor Chia-Chen Hsu at National Chung Cheng University. The wavelength of the incident light was in the range of 190 nm˜1100 nm. The single beam spectrophotometer should be operated for two times. At the first time, the beam passed though a reference sample as a blank and at the second time, the beam passed through a coated test sample and after the passing beams were received by a detector, the detector then converted the difference of light intensity of the two samples to get absorbance or transmittance.

Absorption coefficient (a) and optical band gap (Eg) can be calculated from the transmittance data. As mentioned in Pankove, J. I. Optical Process in Semiconductors (Dover publications, New York, 1971) and Mott, N. F. et al. Electronic Processes in Non-crystalline Materials, 2nd ed. (C₁₋arendon Press, Oxford, 1979), a can be derived from an equation of film thickness (d), transmittance (T) and reflectivity (R) wherein the equation is

$$α = \frac{1}{d} ln [ \frac{{( 1 - R )}^{2}}{T} ] \qquad ( Eq . 3 \text{-} 9 )$$

The reflectivity (R) can be ignored if it is smaller than 0.25 and equation 3-9 can be simplified as

$$α = \frac{1}{d} ln [ \frac{1}{T} ] \qquad ( Eq . 3 \text{-} 10 )$$

Tauc J. et al. Non-cryst. Solids 8-10, 569-585 (1972) by J. Tauc in 1972 states an equation of optical band gap (Eg) as

αhv=const.(hv−E_{g})^{m} (Eq. 3-11)

In equation 3-9, where α is absorption coefficient, Eg is optical band gap of materials, hv is the energy of incident photons and m=1/2, 2, 3/2, wherein 3 represents 4 different modes of electron excitation as allowed direct, allowed indirect, forbidden direct, and forbidden indirect respectively.

As mentioned in Hecht E. OPTICS, 4th ed, Addison Wesley, 2002, by using UV-Visible spectrophotometer, an incident light is transmitted vertically into the test sample, and the reflectivity of the materials is calculated by equation 3-12:

$$R = {( \frac{{n}_{1} - {n}_{2}}{{n}_{1} + {n}_{2}} )}^{2} \qquad ( Eq . 3 \text{-} 12 )$$

8. Optical Characteristics Measurement Equipment: Spectroscopic Ellipsometer System

To measure optical characteristics of thin films, refractive index of thin films and thickness are important optical constants of optical thin films Ellipsometry is a method means using optical technique to measure the surface properties of thin films and is non-contact and nondestructive. A change in polarization state happens when a polarized laser beam passes through a surface of an object and the ellipsometer measures the change (the variation of amplitude and the variation of phase of incident light and reflected light) by detecting the reflected light from the surface to determine the surface properties, refractive index of thin films, extinction coefficient (k) and the film thickness.

Instead of measuring the physical parameters of the samples directly, ellipsometer must determine the physical properties of the samples through a model and to obtain the actual physical parameters of the samples by numerical analysis. As a result, the method of numerical analysis determines the accuracy and the application scope of the ellipsometer. The ellipsometer mainly measures different ratios of the variation of polarization instead of measuring absolute intensities of light, thus increasing the accuracy of measurements. For simpler structures, the ratios of variation can be calculated by geometric progression. For multi-layer structures, due to the interactions between each layer, iterative method is used to calculate the transmission coefficient and reflection coefficient layer by layer by program calculation instead of by geometric progression.

The SpecEL-2000 spectroscopic ellipsometer system in the present embodiment was from Professor Lai-Kwan Chau's lab of Department of Chemistry and Biochemistry at National Chung Cheng University and was manufactured by Mikropack Corporation.

9. Material Analyzer: Grazing Incident X-Ray Diffraction (GI-XRD)

The conventional X-ray Diffraction adopts symmetric Bragg diffraction to analyze the structure of materials. The incident light and the reflective light are symmetric, namely, the angle between the incident light and the sample surface is equal to the angle between the reflective light and the sample surface. The transmission depth of X-ray is in proportion to sin θ/μ wherein θ is incident angle and μ is linear absorption of material. For most materials, the 1/μ value far exceeds the film thickness, and thus the ratio of a thin film signal to diffracted signals measured under this situation is very low, and moreover, the thin film signal may not be recognized due to shielding by the background radiation generated by the substrate scattering. As a result, to measure the structure of a nano thin film, the present invention used high resolution diffraction in Instrument Center at National Chung Hsing University, and the high resolution diffraction was manufactured by BRUKER AXS Corporation in Germany and the product type was D8 Discover SSS. The high resolution diffraction provides grazing incident X-ray diffraction (GI-XRD) service and is a timely and nondestructive analyzer, and thus it is an efficient instrument to study different lattice structures of material. With the high resolution X-ray diffraction, the information of lattice structures of material is measured in order to study the change of material properties.

10. Material Analyzer: Alpha Step

The Alpha step used to measure film thickness was from Professor Wen-Cheng Chang's lab of Department of Physics at National Chung Cheng University (brand: KLA Tencor, product type: Alpha-Step 500). The working principle was to use a probe to process a contact and destructive scan on the sample surface, and measured the surface-relief and amplified the signals of the region through which the probe passed, and the difference in height was calculated by a controller.

11. Material Analyzer: X-Ray Photonelectron Spectroscopy (XPS)

X-ray photonelectron spectroscopy also known as electron spectroscopy for chemical analysis (ESCA) is broadly applied to the analysis of the bonding state between elements of material. The basic principle of XPS is based on photoelectric effect. When X-ray illuminates on a surface of a material, X-ray bombards the atoms on the surface and excites photoelectrons. Analyzing the characteristic kinetic energy with an electron energy analyzer identifies the element of the surface atoms. If the energy of X-ray is larger than binding energy of an inner shell electron and the work function, the electron is then ionized to be a free electron and emits a photoelectron. The binding energy (B.E.) of the electron can be calculated by measuring the change of kinetic energy of the photoelectron and to determine the elemental composition and the chemical state of the emitting photoelectron. The equation is

B.E.=hv−K.E.−Φ_{SPECT} (Eq. 3-13)

Where B.E. is binding energy, K.E. is kinetic energy and Φ_{SPECT} is work function.

A phenomenon of interchanging between electrons occurs due to the valence electrons of the atoms of a compound participating in bonding, so the atoms are not neutral. The elements with high electronegativity have a negative charge while the elements with low electronegativity have a positive charge, and thus the inner shell electrons are affected by the static electric field and change the energy levels. The positive charge will cause the reduction of kinetic energy of the photoelectrons of elements, that is, the binding energy of the photoelectron measured by analyst is higher than the binding energy of the atomic state. On the contrary, the measurement of the binding energy of the photoelectron of elements with a negative charge will shift to a lower value.

Because the chemical environments surrounding each element of a compound are very different, this property can be used to identify the ESCA spectra thereof. For example, the binding energy of an element changes if the element is bonded to an atom having a high electronegativity. The element that is bonded to an atom having a higher electronegativity or is bonded to more atoms having high electronegativities has a higher binding energy. The element that is bonded to an atom having a lower electronegativity or is bonded to more atoms having low electronegativities has a lower binding energy. A general rule is to judge the change of electron binding energy caused by the change of chemical state or oxidation state of a compound. Electron binding energy will be larger if valence electrons are ionized or the oxidation states increase. On the other hand, electron binding energy will decrease if valence electrons increase or the oxidation states decrease. The XPS measuring of the present invention was operated by Instrument Center at National Chung Cheng University.

12. Material Analyzer: Atomic Force Microscope (AFM)

Atomic force microscope is to study the topography of a sample surface at the nanoscale. The basic principle of the atomic force microscope is based on the van der Waals force between the probe and the sample, and the distance between the probe and the sample affects the van der Waals force. Because the cantilever is flexible, the cantilever will be bent and deformed by the change of the force. The Z scanner controls the AFM probe and gives information of the displacement by measuring the extent of bending and deformation of the cantilever probe caused by the force wherein the information is the surface structure of the sample. The AFM used in the present invention was high resolution probe microscope from Instrument Center at National Chung Cheng University and was manufactured by Veeco Corporation and the product type was NanoMan NS4+D3100. The instrument is famous for its high precision and high stability.

13. Materials

Table 1 shows the materials involved in the embodiments of the present invention.

TABLE 1

| Reagents and consumables | Specifications | Supplier |
|---|---|---|
| P+ silicon wafer | Lattice orientation | Wafer Works |
| | (100), | Corporation |
| | resistivity | |
| | 0.001~0.025 Ω | |
| Acetic acid (Hac, C₂H₄O₂) | Purity: 99.5% | Alfa Aesar, |
| | | U.S.A |
| 2-Methoxyethanol | Purity: 99.5% | Merck, Germany |
| (2-MOEC₃H₈O) | | |
| Zinc(II) nitrate hydrate | Purity: 99.99% | Merck, Germany |
| (Zn(NO₃)₂•6H₂O) | | |
| Indium (III) nitrate hydrate | Purity: 99.99% | Alfa Aesar, |
| (In(NO₃)₃•xH₂O) | | U.S.A |
| Yttrium (III) nitrate hydrate | Purity: 99.9% | Alfa Aesar, |
| (Y₂(NO₃)₃•xH₂O) | | U.S.A |
| Acetone (CH₃COCH₃) | Purity: 99.5% | Mallinckrodt |
| | | chemicals |
| Isopropanol (C₃H₈O) | Purity: 99% | J. T. Baker |
| photoactive compound | AZ 4620 | AZ |
| photoactive compound | TR-400 | eChem Solutions |
| | | Corporation. |
| developer 2.38% TMAH | 2.38% | Alfa Aesar, |
| (Tetramethylammonium | | U.S.A |
| hydroxide, (CH₃)₄NOH) | | |
| Aluminum ingot | Purity: 99.999%, 6 | LJ-UHV corporation |
| | mm*6 mm | |

### Second Embodiment

The present embodiment relates to the cleaning procedure of the silicon substrates.

To ensure the quality of the coating, the substrates must be cleaned before coating in order to remove organic-matter and dust. The cleaning procedure of the substrates comprised sequential steps as follows:

1. A substrate was put in a crystallizing basin containing diluted detergents (diluted with deionized water), and then the crystallizing basin was put into a sonicator to sonicate for 10 minutes in order to remove the oil on the substrate surface. The substrate was washed with deionized water, and then the substrate was dried.

2. The substrate was put in a crystallizing basin containing acetone, and then the crystallizing basin was put into a sonicator to sonicate for 10 minutes in order to remove the organic-matter on the substrate surface.

3. The substrate was removed from acetone and was put in a crystallizing basin containing IPA, and then the crystallizing basin was put into a sonicator to sonicate for 10 minutes in order to remove the residual acetone on the substrate surface.

4. The substrate was put in a crystallizing basin containing deionoized water, and then the crystallizing basin was put into a sonicator to sonicate for 10 minutes in order to remove the residual IPA on the substrate surface.

5. Finally, the substrate was dried with nitrogen.

### Third Embodiment

The present embodiment relates to the procedure of preparing solution for coating the active layer.

The molarity of indium and zinc of the active layer used in the present invention was 0.224 M. The ratios of doping amount of yttrium to the molarity of indium were different wherein the doping amounts of yttrium were 0, 2, 4, 6, 8, 12, 14, 20% respectively. The procedure of preparing solution for coating the active layer was as follows:

1. Zinc (II) nitrate hydrate was added into 2′-O-(2-methoxy) ethyl (2-MOE) and zinc (II) nitrate hydrate was dissolved. The dissolving rate of the solute was increased by sonication for 10 minutes to get a solution.

2. Indium (III) nitrate hydrate was added into the solution and indium (III) nitrate hydrate was dissolved. The dissolving rate of the solute was increased by sonication for 10 minutes to get the solution.

3. Yttrium (III) nitrate hydrate was added into the solution and yttrium (III) nitrate hydrate was dissolved. The dissolving rate of the solute was increased by sonication for 10 minutes to get a precursor solution.

4. A stir bar was put into the precursor solution and a stirrer was used to stir the precursor solution for 10 hours to uniformly mix the solute and solvent.

5. After 10 hours, the preparation of the active layer precursor was finished inside the class 100 clean glove box by using a 0.2-μm syringe filter to filter the precursor solution into another sample bottle to remove the impurity particles.

### Fourth Embodiment

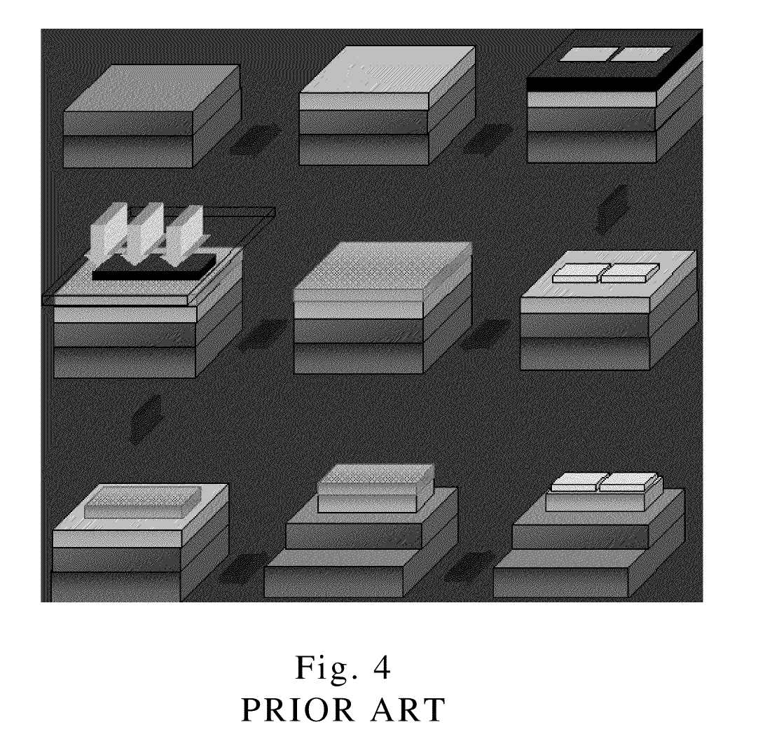

With reference to FIG. 4, the present embodiment relates to the procedure for fabricating a TFT and the procedure comprised sequential steps as follows:

1. National Nano Device Laboratories (NDL) fabricated the dielectric layer wherein the dielectric layer was formed on a substrate and comprised:

a 300 nm thick SiO₂ layer that was grown with a wet oxidation and was carried out in a horizontal tube furnace, a 80 nm thick SiO₂ layer that was grown with a dry oxidation and was carried out in a horizontal tube furnace and a 300 nm thick Si₃N₄ layer that was grown by PECVD at room temperature.

2. Fabricating the active layer by sol-gel process comprised sequential steps as follows:

A precursor of active layer was prepared by sol-gel process; the spin coater was used to spin coat the precursor of the active layer on the dielectric layer on the substrate; the organic carbon chain of the precursor was broken by soft baking and sintering, and thus the precursor became an inorganic active layer materials. With a non-vacuum process, the fabrication time of active layer was shortened reduced, the fabrication cost of active layer decreased and an accurate ratio of doping elements was obtained.

3. Evaporating aluminum electrode comprised sequential steps as follows: The Shadow mask was used to define source and drain electrodes; thermal evaporation was used to evaporate aluminum wherein the aluminum formed an Ohmic contact with the active layer; the output current was increased; and the width (W) and the length (L) of the channel were defined wherein the W was 1000 μm and the L was 100 μm.

4. Isolating the active layer region comprised sequential steps as follows: mask was used to define the active layer region and diluted HF was used to remove the unwanted active layer part so as to isolate each element and prevent each element from being affected by adjacent elements. The exposure lithography was used to define the active layer region, which prevented leakage current and fringing current.

### Fifth Embodiment

The present embodiment relates to the effects on the properties of TFT with the defined active layer and with the active layer undefined.

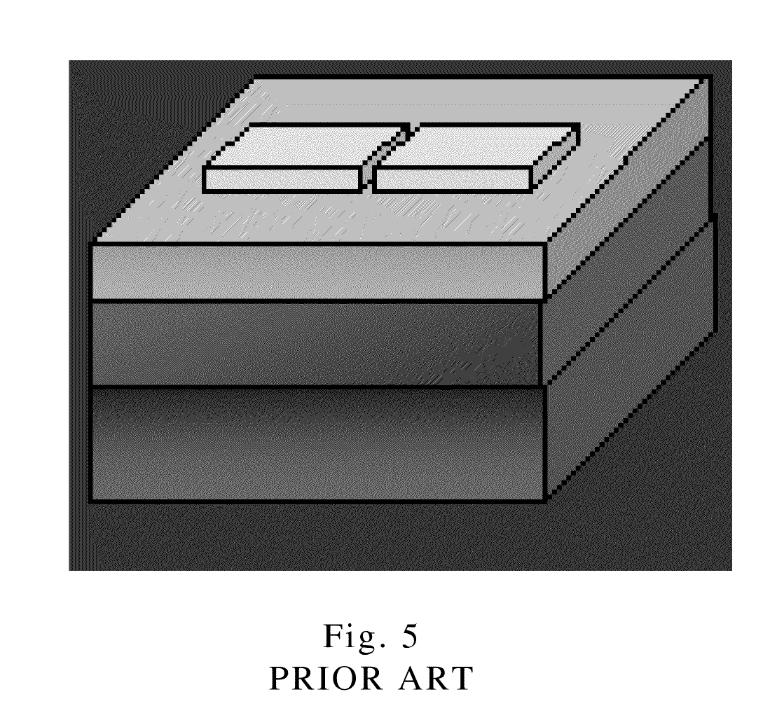

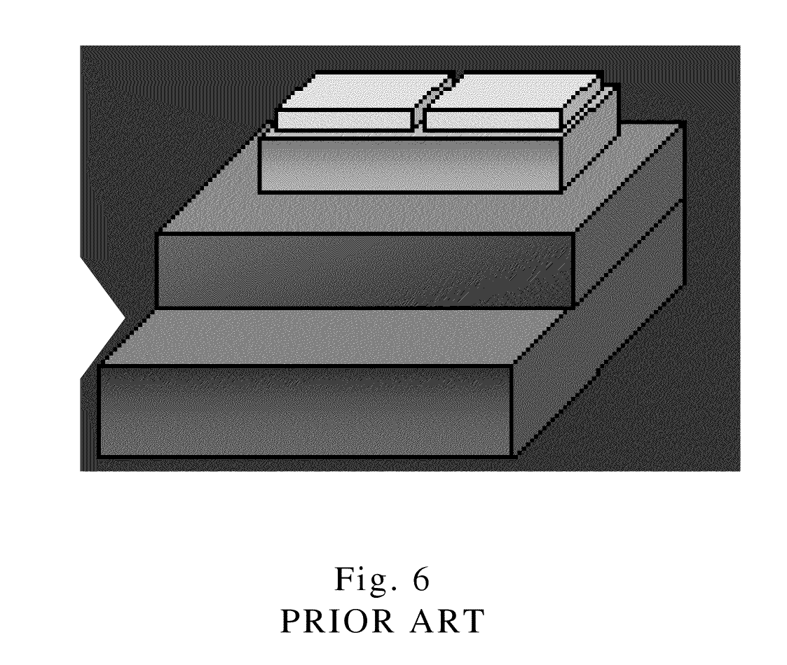

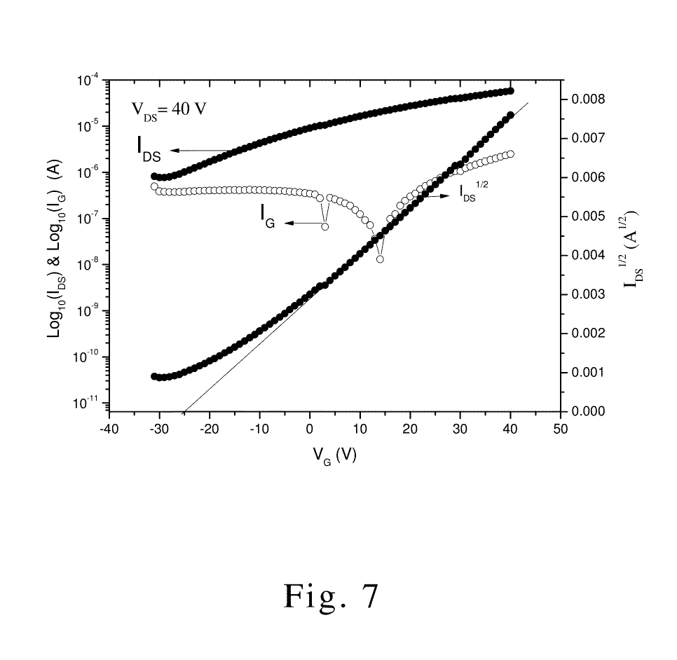

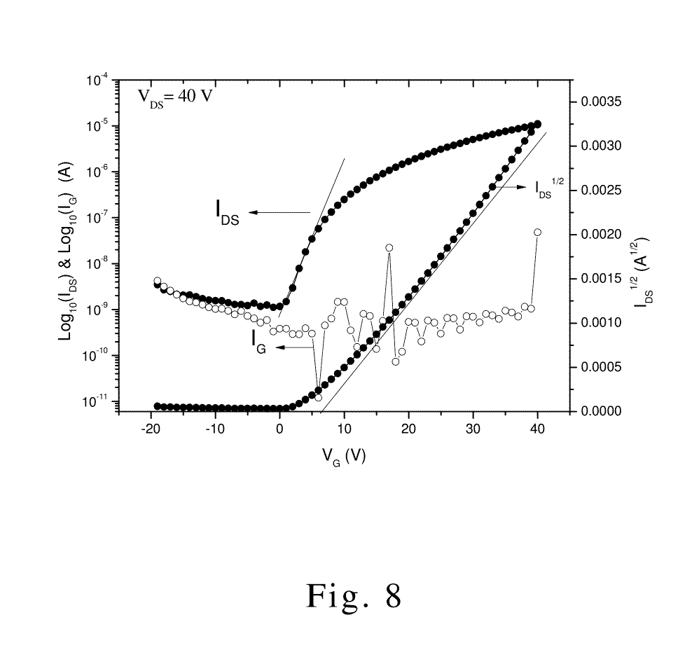

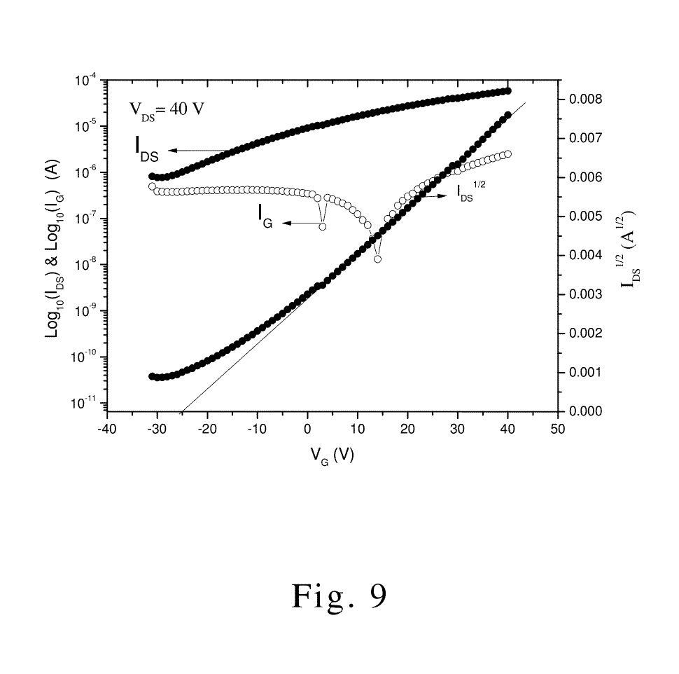

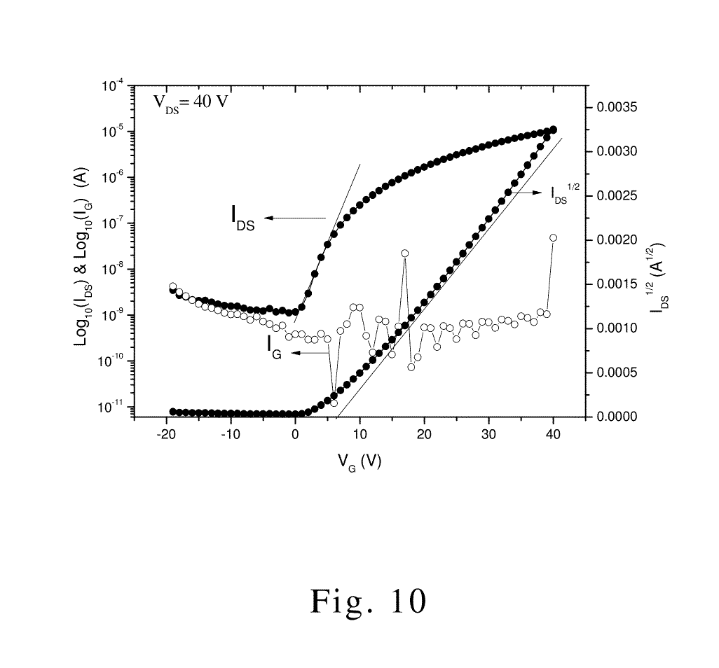

In the early stage of fabricating TFT, leakage current of the TFT devices was the major problem. The cause of leakage current was found to be that the TFT with the active layer undefined was not able to suppress leakage current. The present embodiment used exposure lithography to define the active layer in order to isolate each TFT element. The active layer used in the present embodiment was IZO and the molarity of zinc equals to the molarity of indium of the IZO. Spin coater was used to spin coat the IZO on a substrate, and followed by sintering for one hour at 400° C. Aluminum electrode was used as source and drain electrode and silicon substrate were used as gate electrode. The processing was similar, and the only difference lied in whether the active layer was defined by exposure lithography and wet etching or not. The structures are shown in FIG. 5 and FIG. 6. With reference to FIG. 7, when V_{DS} is low, the leakage current of the TFT with the active layer undefined is large and a negative current is observed. However, with reference to FIG. 8, no such phenomenon exists in the TFT with the defined active layer. Moreover, FIG. 9 is compared with FIG. 10 to study the transfer characteristic curve of TFT. The TFT with the active layer undefined exhibits an off current (I_{off}) of 7.84×10⁻⁷ A and the maximum of the output current (Iₒₙ) of 1.59×10⁻⁴ A, with reference to FIG. 7. The TFT with the defined active layer exhibits an I_{off} of 1.11×10⁻⁹ A and the maximum of Ion of 1.05×10⁻⁵ A, with reference to FIG. 8. As a result, the I_{on/off} ratio of the TFT with the defined active layer is two orders of magnitude less than the I_{on/off} ratio of the TFT with the active layer undefined. In conclusion, the TFT with the defined active layer is able to suppress leakage current of the device effectively.

### Sixth Embodiment

The present embodiment relates to TFT properties affected by different doping concentrations of yttrium.

In the present embodiment, an 80 nm thick SiO₂ layer as dielectric layer was grown with a dry oxidation and was carried out in a horizontal tube furnace, the heavily doped boron silicon wafer was used as the gate electrode, and aluminum was used as source and drain electrode. In the preliminary study, the sintering temperature was 400° C. but the resulting TFT properties were not good, and thus the sintering temperature was adjusted to 500° C. and the substrates with active layers were sintered for one hour to study the TFT properties. The resulting output characteristic curve (I_{DS}−V_{DS}) and transfer characteristic curve (I_{DS}−V_{GS}) are described as follows:

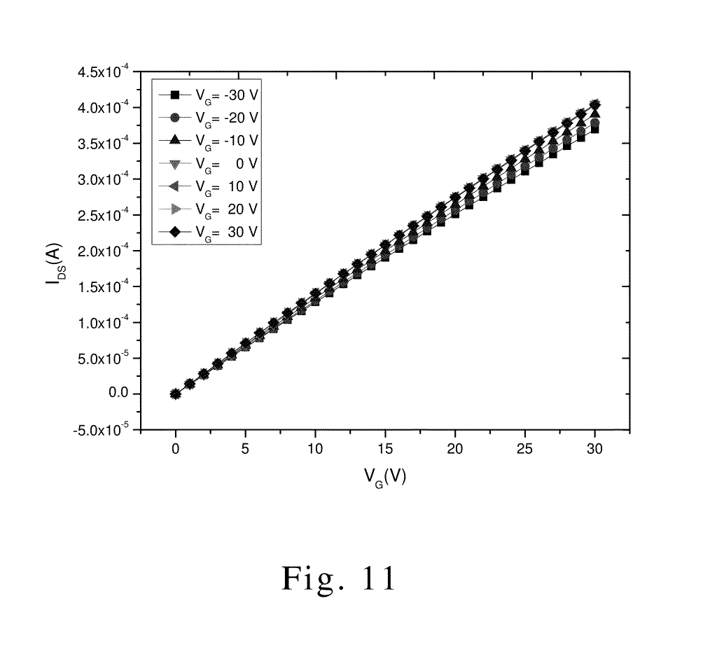

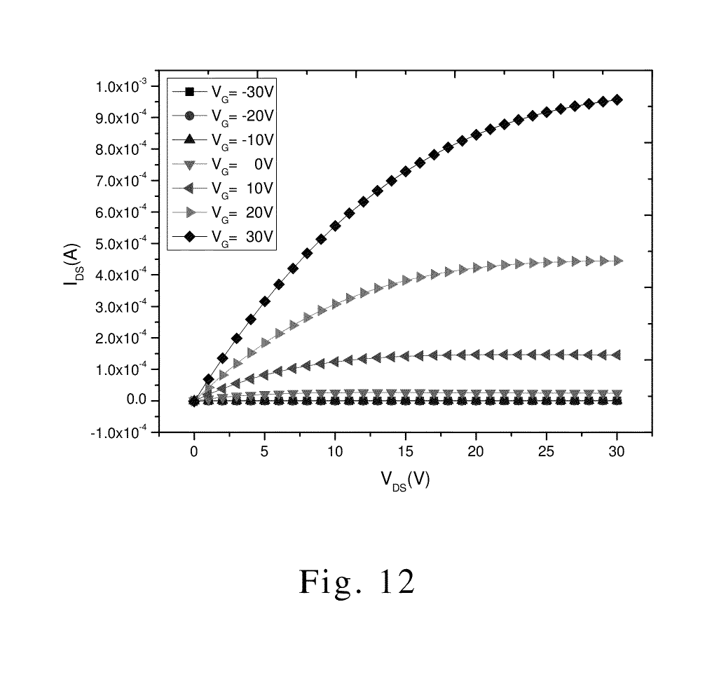

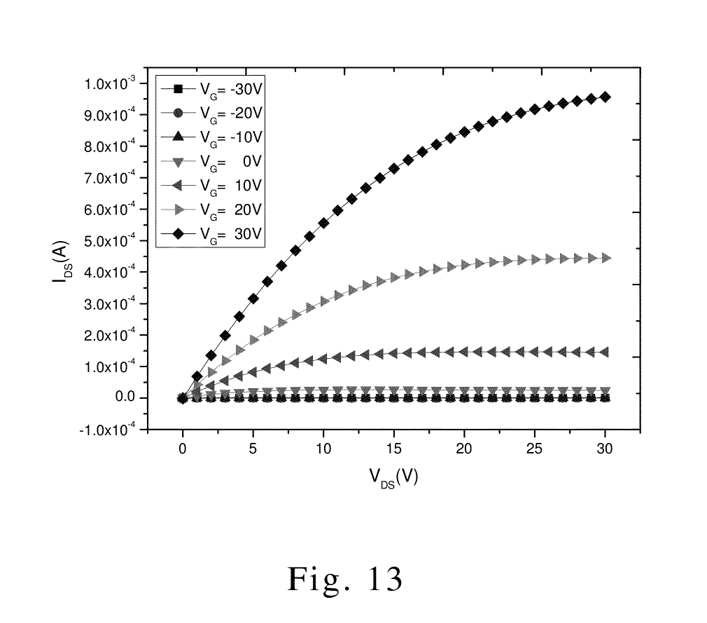

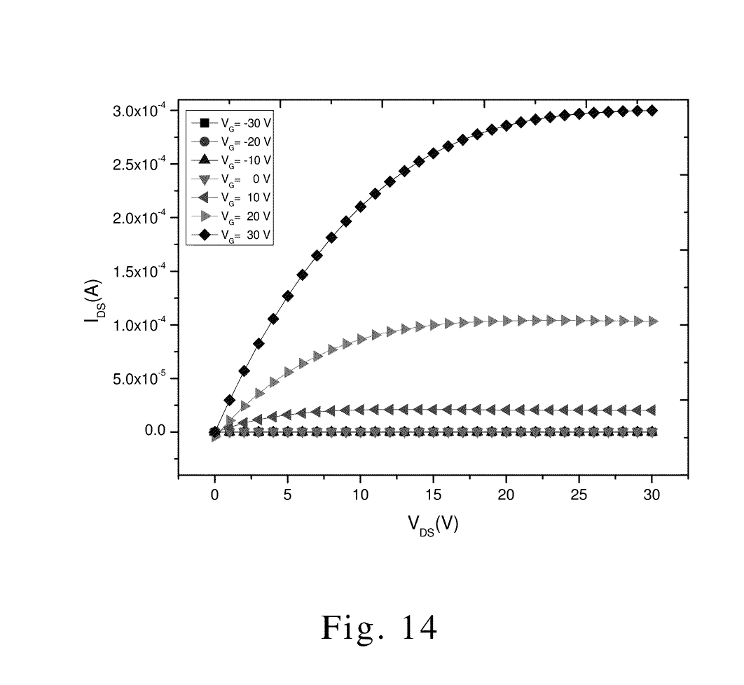

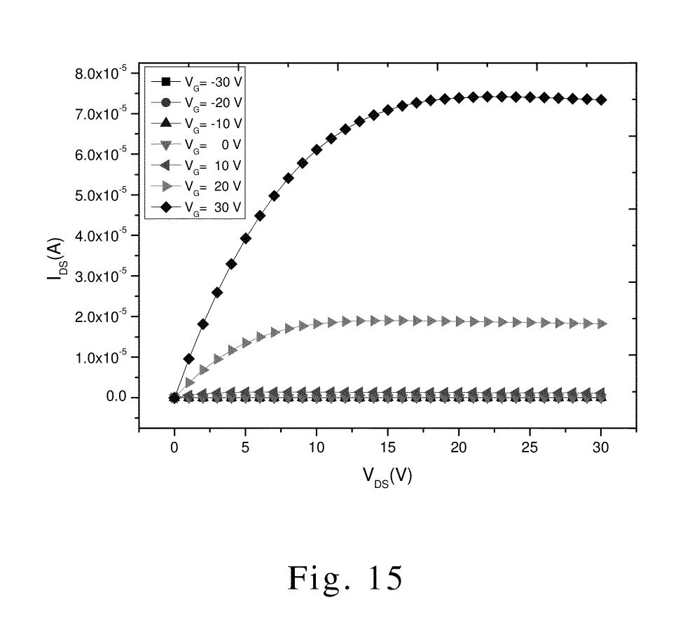

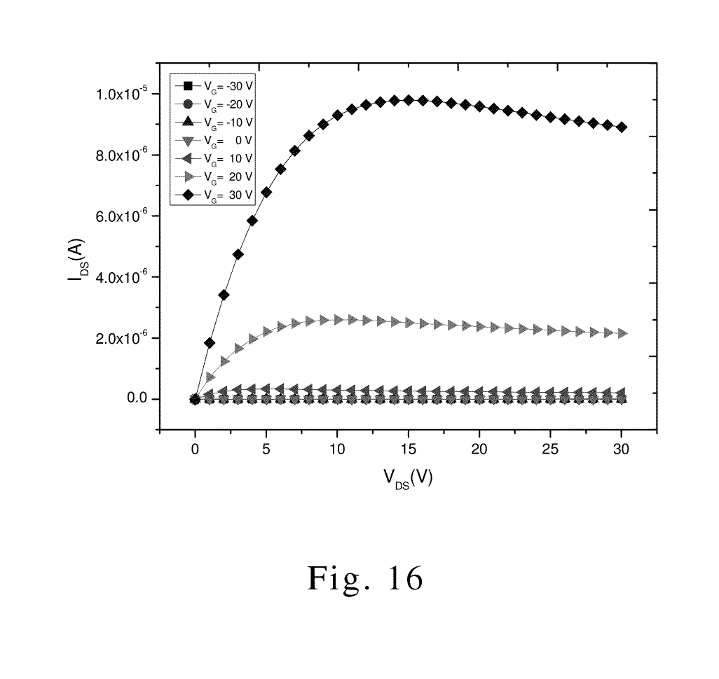

Diagrams of transfer characteristic curve (I_{DS}−V_{GS}) of TFT with different doping ratios of yttrium are shown in FIG. 11 to FIG. 16. The step V_{GS} was −30 to 30 V, and the V_{DS} was swept from 0V to 30V. When the doping ratio of yttrium is 0, the TFT exhibits similar metal conductive properties, and shows linear region but shows no saturation region. When the doping ratio of yttrium is 6-8% and when V_{GS} is 0 V, the TFT devices are still in the on-state and the TFT devices are called depletion-mode TFTs. With doping ratios of yttrium increasing to 12%, 14% and 20%, obvious saturation regions exist and when V_{GS} is 0 V, the TFT devices are in the off-state and the TFT devices are called enhancement-mode TFTs. With reference to FIG. 12 to FIG. 15, the TFT shows linearity when V_{Ds} is very low, the source and drain electrode form an Ohmic contact with the active layer, which indicates that the potential barrier of aluminum contacting YIZO thin film is small, and thus charges easily overcome the potential barrier and reduce the energy loss of charges. With reference to FIG. 12 to FIG. 15, the more the doping amount of yttrium, the smaller the output current.

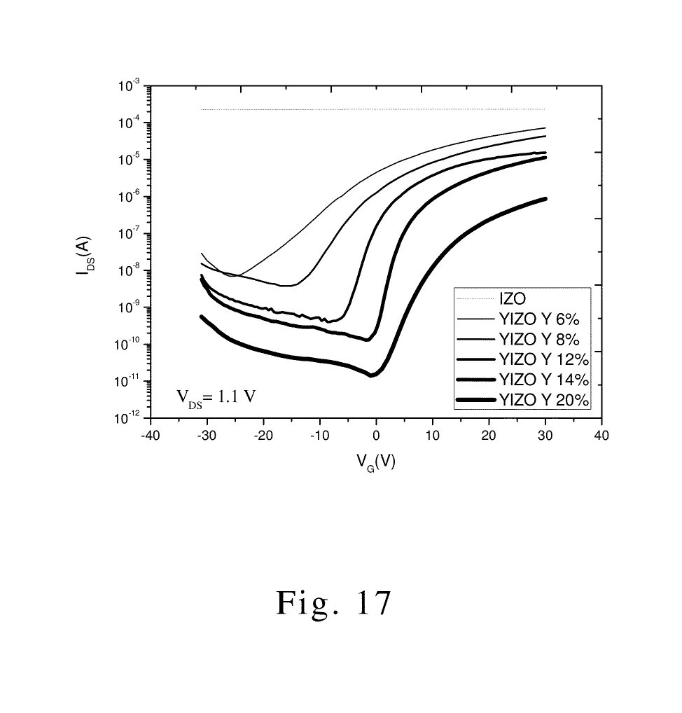

To study the linear region properties of TFT, a constant V_{DS} of 1.1 V was applied and the V_{GS} was swept from −30V to 30V. The diagram of transfer characteristic curve (I_{DS}−V_{GS}) of TFT with different doping ratios of yttrium is shown in FIG. 17. Equations 2-3 to 2-11 are used to obtain data, and the data is shown in Table 2.

TABLE 2

| Y | | | | μₗᵢₙ | Vₒₙ | V_{T} | | |
|---|---|---|---|---|---|---|---|---|
| (%) | Iₒₙ (A) | I_{off} (A) | I _{on/off} ratio | (cm²/Vs) | (V) | (V) | S.S. | N_{SS}^{max} |
| 0% | 2.31 × 10⁻⁴ | 2.26 × 10⁻⁴ | 1.02 | NA | NA | NA | NA | NA |
| 6% | 7.18 × 10⁻⁵ | 6.95 × 10⁻⁹ | 1.03 × 10⁴ | 6.46 | −25 | 6.65 | 8.02 | 8.38 × 10¹³ |
| 8% | 4.31 × 10⁻⁵ | 3.78 × 10⁻⁹ | 1.14 × 10⁴ | 4.42 | −19 | 9.96 | 4.48 | 4.67 × 10¹³ |
| 12% | 1.54 × 10⁻⁵ | 3.99 × 10⁻¹⁰ | 3.85 × 10⁴ | 2.04 | −9 | 3.46 | 2.04 | 2.11 × 10¹³ |
| 14% | 1.13 × 10⁻⁵ | 1.10 × 10⁻¹⁰ | 1.03 × 10⁵ | 1.38 | −1 | 14.28 | 1.41 | 1.45 × 10¹³ |
| 20% | 1.72 × 10⁻⁶ | 3.50 × 10⁻¹¹ | 5.64 × 10⁴ | 0.33 | 1 | 16.07 | 2.46 | 2.55 × 10¹³ |

When yttrium is 0%, the device shows no switching characteristics and exhibits a phenomenon of normally on. With increasing doping ratios of yttrium from 0% to 20%, Iₒₙ shows a declining trend from 10⁻⁴ to 10⁻⁶ A, and I_{off} shows a more obvious declining trend from 10⁻⁴ to 10⁻¹¹ A. Vₒₙ shows a trend of shifting toward positive voltage from −25V to 1V, which indicates that the device will achieve off-state under smaller negative gate voltage. As a result, the carrier concentration of the active layer will decrease as the doping amount of yttrium increases.

To study subthreshold swing (S.S.), equation 2-10 was used to calculate S.S. When the doping amount of yttrium is 14%, the TFT exhibits a minimum S.S. of 1.59 V/decade, which indicates that in all devices with different doping concentrations of yttrium, V_{GS} required to make the TFT shift from off-state to on-state is the least of the TFT with 14% doping concentrations of yttrium.

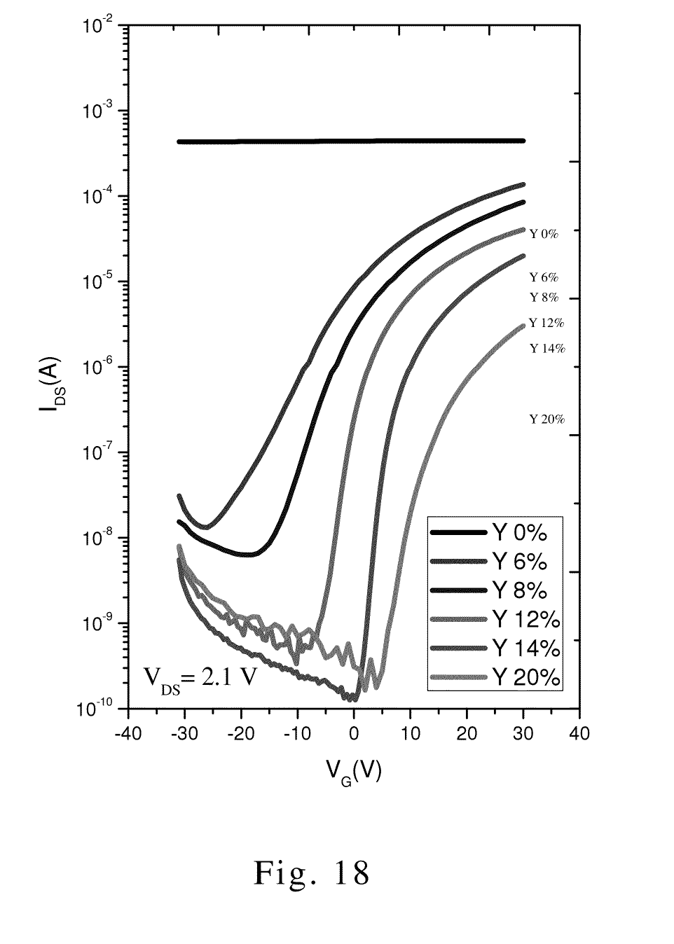

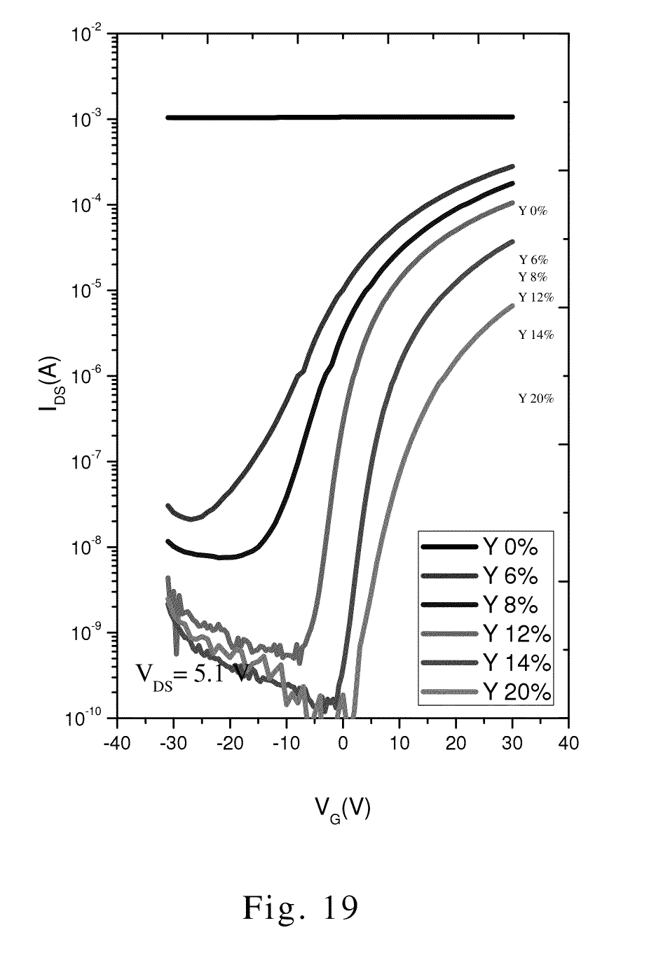

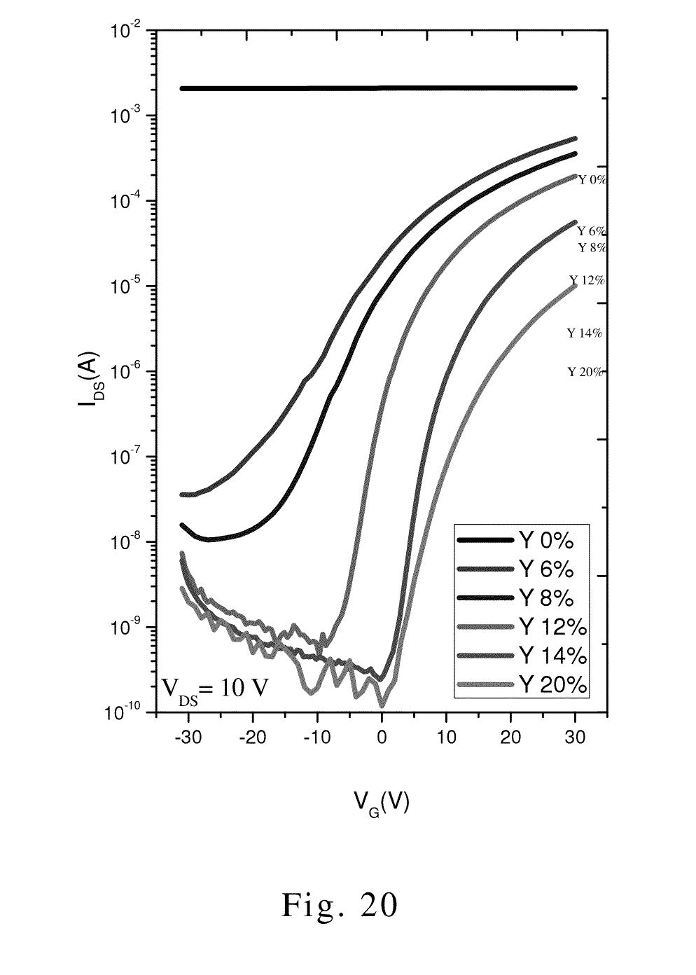

Besides, the transfer characteristic curve was measured by applying a constant V_{DS} of 1.1 V, 5.1V and 10 V, with reference to FIG. 18 to FIG. 20. With increasing doping amount of yttrium, the output current exhibits a declining trend, I_{off} shows a more obvious declining trend and Vₒₙ shows a trend of shifting toward positive voltage.

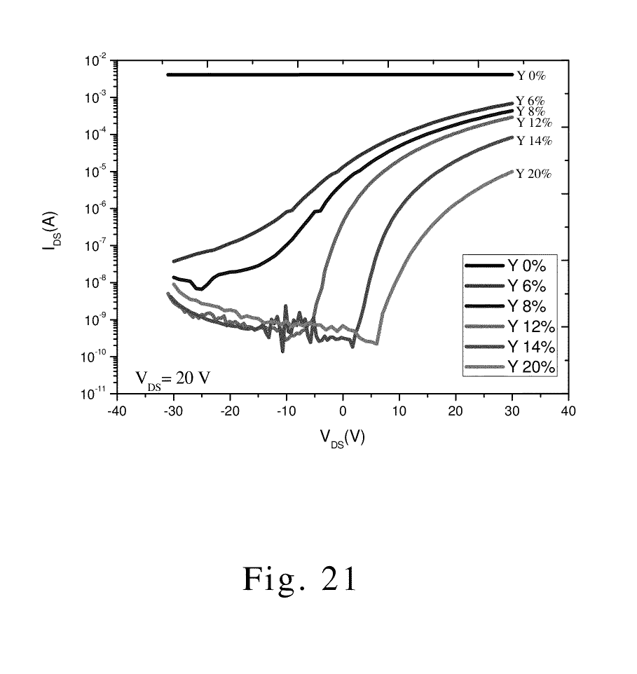

To study the saturation region properties of TFT, a constant V_{DS} of 20 V was applied and the V_{GS} was swept from −30V to 30V. The diagram of transfer characteristic curve (I_{DS}−V_{GS}) of TFT with different doping ratios of yttrium is shown in FIG. 21 and the data is shown in Table 3.

TABLE 3

| Y | | | | μ_{Sat} | Vₒₙ | V_{T} | | |
|---|---|---|---|---|---|---|---|---|
| (%) | Iₒₙ (A) | I_{off} (A) | I _{on/off} ratio | (cm²/Vs) | (V) | (V) | S.S. | N_{SS}^{max} |
| 0% | 4.15 × 10⁻³ | 4.08 × 10⁻³ | 1.02 | NA | NA | NA | NA | NA |
| 6% | 6.88 × 10⁻⁴ | 3.71 × 10⁻⁸ | 1.85 × 10⁴ | 3.33 | −30 | −0.96 | 8.24 | 9.97 × 10¹³ |
| 8% | 4.35 × 10⁻⁴ | 6.59 × 10⁻⁹ | 6.6 × 10⁴ | 3.27 | −25 | 1.69 | 6.14 | 5.91 × 10¹³ |
| 12% | 2.91 × 10⁻⁴ | 2.23 × 10⁻¹⁰ | 1.3 × 10⁶ | 2.08 | −6 | 3.68 | 1.55 | 1.59 × 10¹³ |
| 14% | 8.41 × 10⁻⁵ | 1.82 × 10⁻¹⁰ | 4.62 × 10⁵ | 1.17 | 2 | 11.76 | 1.84 | 1.9 × 10¹³ |
| 20% | 1.13 × 10⁻⁵ | 2.20 × 10⁻¹⁰ | 5.12 × 10⁴ | 0.22 | 6 | 14.54 | 2.74 | 2.84 × 10¹³ |

When yttrium is 0%, the device shows no switching characteristics and exhibits a phenomenon of normally on. With doping ratios of yttrium increasing from 0% to 20%, Iₒₙ shows a declining trend from 10⁻³ to 10⁻⁵ A, and I_{off} shows a more obvious declining trend from 10⁻³ to 10⁻¹⁰ A. Vₒₙ shows a trend of shifting toward positive voltage from −30V to 6V. V_{T} also shows a trend of shifting toward positive voltage from −0.96V to 14.54V. Moreover, with increasing doping amounts of yttrium, μₛₐₜ decreases from 3.33 to 0.22 cm²/Vs.

Equation 2-10 was used to calculate S.S and equation 2-11 was used to max calculate N_{SS}^{max}. Within different doping ratios of yttrium, the TFT with a 12% doping ratio of yttrium exhibits a minimum S.S. of 1.55 V/decade and a least maximum defect amount of 1.59×10¹³. Information of transfer characteristic curves with different doping ratios of yttrium is shown in Table 3, a constant V_{DS} of 20V was applied, and _{VG} was swept from −30V to 30V. The TFT with a 12% doping ratio of yttrium of YIZO exhibits best properties as Iₒₙ of 2.91×10⁻⁴ A, I_{off} of 2.23×10⁻¹⁰ A, I_{on/off} ratio of 1.3×10⁶, μₛₐₜ of 2.08 cm²/Vs, Vₒₙ of −6 V, V_{T} of 3.68 V and S.S of 1.55 V/decade.

Electrical characteristics of a series of TFTs with different doping concentrations were analyzed. The best doping concentration of yttrium of TFT was 12%, and the TFT with 12% doping concentration of yttrium exhibited S.S of 1.55 V/decade, which indicated that to increase output current by one order, the necessary V_{G} was 1.55 V, but the S.S still needed to be improved to less than 1 V/decade. Equation 2-11 and S.S value were used to calculate maximum defect amount of the active layer/dielectric layer interface, the amount of defect might be attributed to the many defects on the heavily doped boron p-Si surface of the gate electrode and the properties of the resulting active layer are affected while depositing SiO₂ dielectric layer on a rough surface with a dry oxidation and being carried out in a horizontal tube furnace.

### Seventh Embodiment

The present embodiment relates to the analysis of lattice structure of the active layer of YIZO thin film with different concentrations of yttrium, wherein the lattice structure is measured by GI-XRD.

To measure the lattice structure of thin films, GI-XRD in Instrument Center at National Chung Hsing University was used to study the lattice structure of yttrium-doped indium zinc oxide thin films The measurement parameters were: grazing incident X-Ray diffraction: θ=0.5°, scanning interval: 0.01°, scanning speed 2°/min and scanning range: 10˜80° respectively.

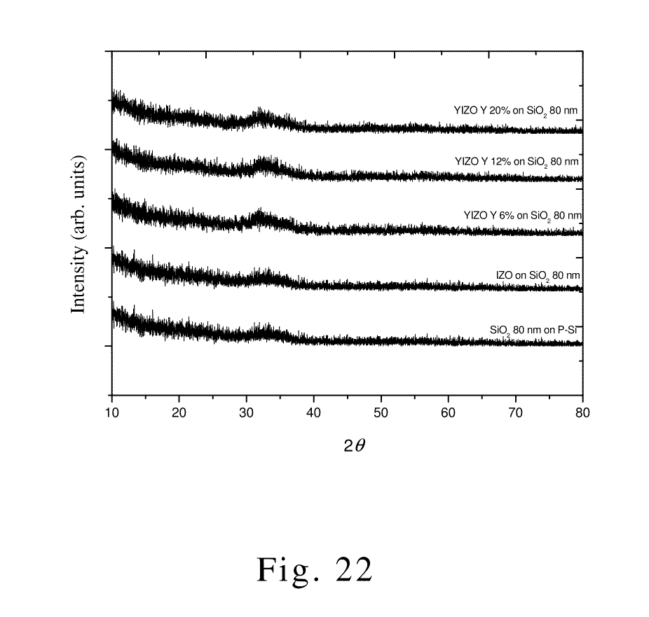

The structure of zinc oxide (ZnO) is hexagonal close packed and the structure of indium oxide (In₂O₃) is cubic. In 2011, Banger, K. K. et al. Nature materials 10, 45-50 (2011), published in Nature material by H. Sirringhaus et, al, mentioned that when indium zinc oxide materials contain an excess amount of indium or zinc, the crystalline phase will exist. The present invention used sol-gel process to fabricate yttrium-doped indium zinc oxide thin film wherein the molarity of indium to the molarity of zinc was 1:1. Different doping concentrations of yttrium were spin coated on the SiO₂ substrates of an 80 nm thickness by the spin coater. The substrates were soft baked for 10 minutes at 200° C. by a heating plate and followed by sintering the substrates at 500° C. for one hour. Finally, GI-XRD was utilized to process measuring. According to the results of experiments, as shown in FIG. 22, the value of 2θ is about 30 to 40 degree. The small lumps formed in FIG. 22 are not attributed to the structure of yttrium-doped indium zinc oxide because these small lumps already exist in the GI-XRD spectrum of the SiO₂ substrates by GI-XRD. It is reasonable that the small lumps are not caused by the lattice structures of yttrium-doped indium zinc oxide materials. Moreover, FIG. 22 shows no crystalline phases of yttrium oxide (Y₂O₃), ZnO and In₂O₃, and thus yttrium-doped indium zinc oxide is proved to be an amorphous phase structure.

The amorphous phase structure may be attributed to the differences between ionic radii of component elements. The ionic radiuses of yttrium, indium zinc, and oxygen are 0.212 nm, 0.156 nm, 0.142 nm and 0.048 nm respectively, wherein the differences between ionic radii of the three metals cause the disorder of the structure.

### Eighth Embodiment

The present embodiment relates to the analysis of carrier mobility, carrier concentration and resistivity of YIZO thin films with different concentrations of yttrium wherein carrier mobility, carrier concentration and resistivity were measured by 4-point probe and Hall Effect measurements.

To study the yttrium-doped indium zinc oxide thin film, the present embodiment used Van der Pauw method to measure the resistivity and Hall effect. The sample was cut into a field size of 1 cm×1 cm and four corners of the sample were probed to process measuring and each sample was measured for three times to ensure the accuracy. First, the substrates with YIZO thin films were sintered at 500° C. under atmosphere. The results of resistivities of yttrium-doped indium zinc oxide materials with different doping amounts of yttrium vary from 0.189 Ωcm to 30300 Ωcm, as shown in Table 4. With increasing doping amount of yttrium, resistivity increases. Van der Pauw method and two additional neodymium magnets (0.5 Tesla) are used to measure Hall Effect. No matter how much the doping amount of yttrium is (from 0 to 20%), the major carriers are electrons, which is an n-type semiconductor material. The carrier concentration varies from 9.22×10¹⁸ to 8.62×10¹³ cm⁻³, as shown in Table 4. With increasing doping amount of yttrium, carrier concentration decreases.

TABLE 4

| | | Carrier | |
|---|---|---|---|
| YIZO | Resistivity | concentration | μ_{Hall} (cm²/Vs) |
| Y % | (Ω cm) | (cm⁻³) | Hall mobility |
| 0 | 0.189 | 9.22 × 1018 | 3.582 |
| 5 | 8.57 | 1.73 × 1016 | 41.92 |
| 10 | 202 | 1.15 × 1015 | 26.36 |
| 14 | 2100 | 3.05 × 1014 | 9.737 |
| 20 | 30300 | 8.62 × 1013 | 2.388 |

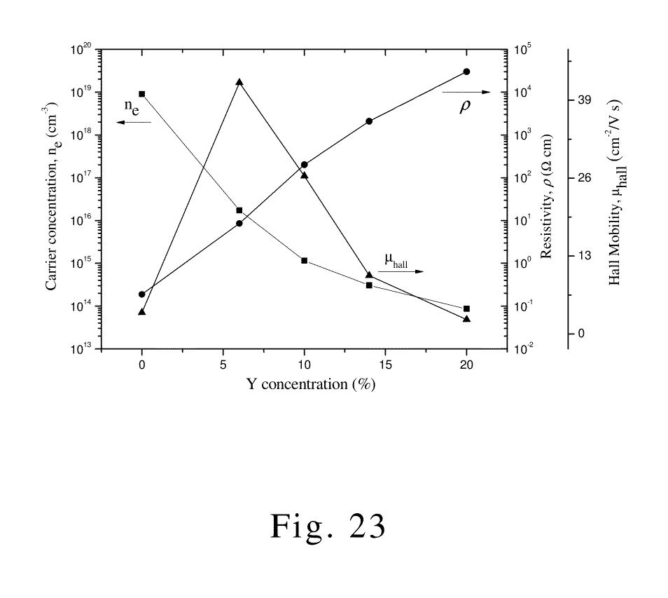

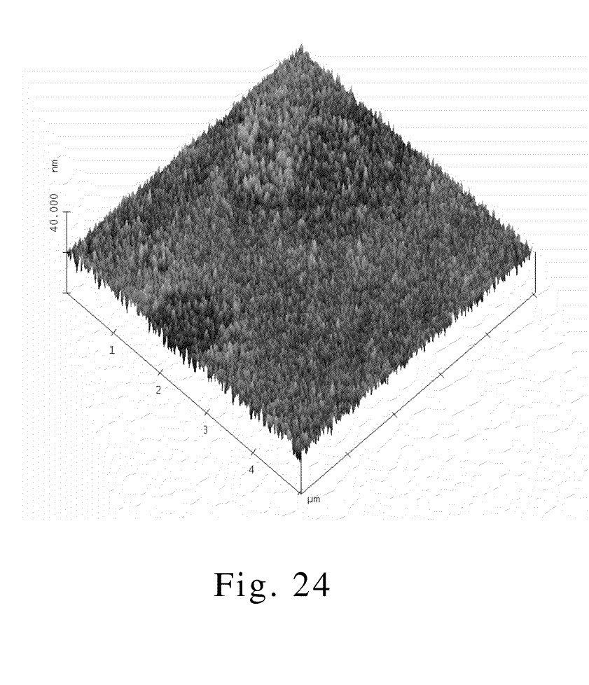

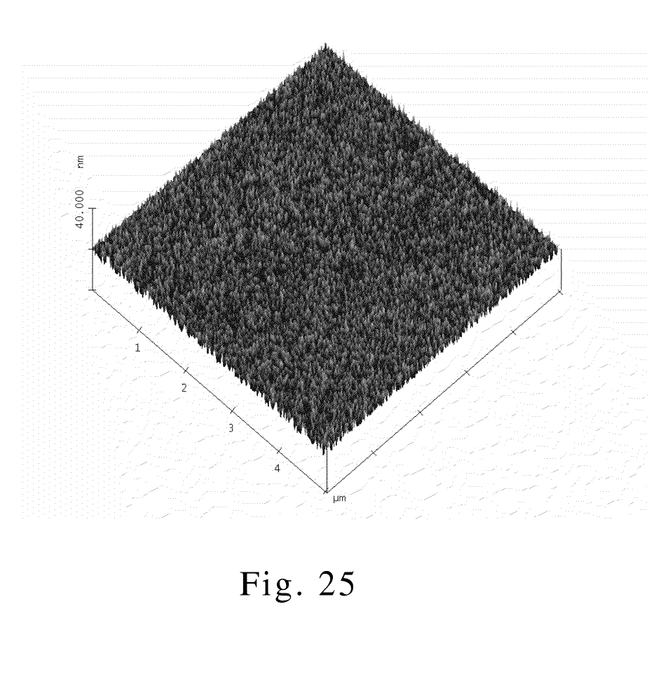

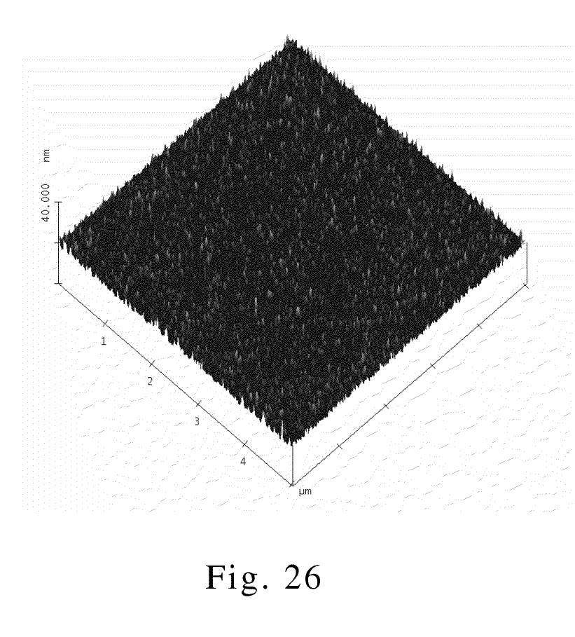

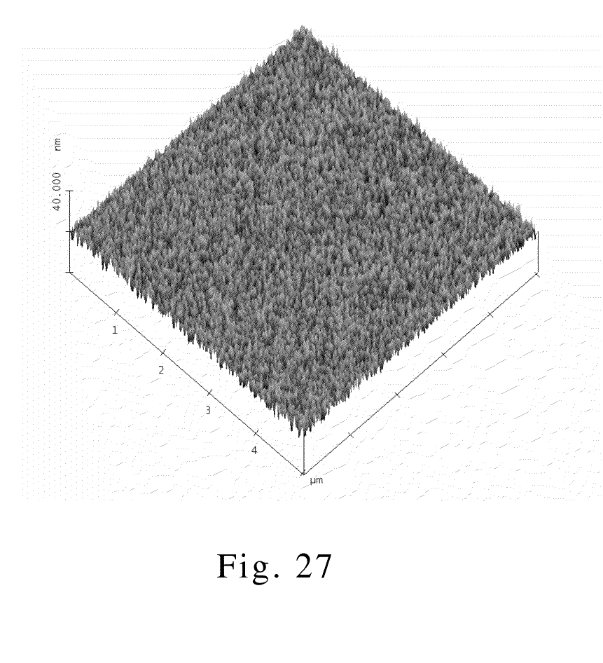

To study Hall mobility (μ_{Hall}), FIG. 23 shows an inverted V pattern. Van der Pauw method was used to measure Hall Effect and the information of electrical characteristics of yttrium-doped indium zinc oxide thin films with different doping concentrations of yttrium (Y=0, 5, 10, 14, 20%) is shown in Table 4. With doping amount of yttrium increasing from 0 to 5%, μ_{Hall} increases from 3.582 to 41.92 cm²/Vs. μ_{Hall} varies from 41.92 to 2.388 cm²/Vs as the doping amount of yttrium is from 5% to 20%. Carrier concentration is the largest when the doping amount of yttrium is 0%. From the later ninth embodiment discussing the surface roughness, when the doping amount of yttrium is 0%, there is a largest surface roughness, with reference to FIG. 24 to FIG. 28. When a material is not at absolute zero, the phonons inside the material will vibrate and cause the bombardment between electron carriers and further increase the phenomenon of scattering, and thus result in reducing μ_{Hall}.

The analysis of the measurements shows that the higher the doping concentration of yttrium, the less the carrier concentration and the larger the resistivity, because the source of the carriers of oxide semiconductors is mainly from oxygen vacancies and free electrons generated from the insertion of metal ions into defects such as vacant positions of oxygen. The results show that doping yttrium into InZnO system effectively binds oxygen and suppresses the formation of oxygen vacancies. From another point of view, the standard electrode potentials (SEP) of yttrium, indium and zinc are −2.65V, −0.34, and 0.76 V respectively. Compared with the standard electrode potentials of the three elements, yttrium has a smallest SEP, which indicates that yttrium is easy to lose electrons to form a steady state with oxygen, and thus the carrier concentration reduces.

### Ninth Embodiment

The present embodiment relates to the surface roughness of yttrium-doped indium zinc oxide thin films with different concentrations of yttrium, wherein the surface roughness was measured by AFM.

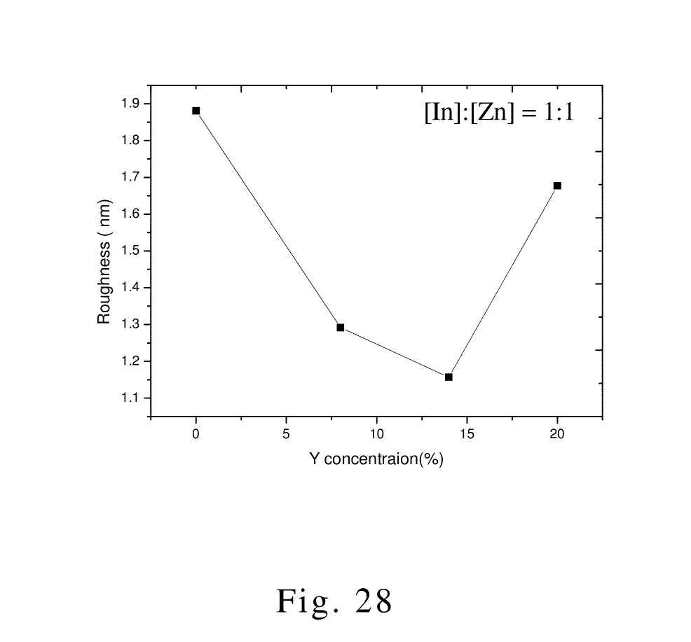

The AFM used in the present embodiment to study the surface roughness of yttrium-doped indium zinc oxide thin films was from Instrument Center at National Chung Cheng University and the measuring range was 5 um×5 um, with reference to FIG. 24 to FIG. 28. The surface roughnesses are 1.881 nm, 1.291 nm, 1.157 nm and 1.677 nm respectively when the doping concentrations of yttrium are 0%, 8%, 14% and 20%. The trend plot of surface roughness with different doping ratios of yttrium is shown in FIG. 28. The surface roughness is smallest when the doping ratio of yttrium is 12% to 14%, and this result conforms to the TFT properties. With reference to Table 2 and Table 3, N_{SS}^{max} is the minimum when the doping ratio of yttrium is 12% to 14% wherein N_{SS}^{max} indicates the maximum defect amount of the active layer/dielectric layer interface. It is assumed that a correlation exists between the surface roughness of the yttrium-doped indium zinc oxide and the defects that are between the yttrium-doped indium zinc oxide thin film and dielectric layer. When the surface roughness is the smallest, the TFT properties are the best.

From the analysis of the measurements obtained by AFM, with doping ratio of yttrium increasing from 0% to 12%, the surface roughness decreases. The results of the previous eighth embodiment shows that the higher the doping concentration of yttrium, the less the carrier concentration, as shown in Table 4, and the results further indicate that the formation of defects was suppressed, thus lowering surface roughness. However, within 12% to 20% doping ratio of yttrium, the surface roughness increases with increasing doping ratio of yttrium, which may be attributed to the larger radius of yttrium ion, thus resulting in increasing surface roughness. The atomic radiuses of yttrium, indium, zinc and oxygen are 0.212 nm, 0.156 nm, 0.142 nm and 0.048 nm respectively.

### Tenth Embodiment

The present embodiment relates to the analysis of refractive index and reflectivity of YIZO thin films with different concentrations of yttrium wherein the refractive index and reflectivity were measured by spectroscopic ellipsometer.

The substrates with YIZO thin films were sintered at 500° C. for one hour, and yttrium of different doping ratios was deposited on SiO₂ substrates, followed by measuring with spectroscopic ellipsometer. Thickness, refractive index and extinction coefficient were obtained by using the change of polarization of incident light and reflected light, and followed by computational simulation. From the results obtained by computational simulation, the change of refractive index is to two decimal places, which indicates refractive index is not a big change. The refractive indexes of different doping concentrations of 0%, 6%, 12% and 20% are 1.5834, 1.52.14, 1.5627 and 1.5477 respectively. The reflectivities are calculated by equation 3-12 and are 0.00073, 0.00005, 0.00042 and 0.00024 respectively. The increasing doping concentrations of yttrium does not change the refractive index of material seriously, as well as reflectivity. The purpose is to prove the result of transmittance spectra obtained by UV-Visible Spectrophotometer and to calculate optical band gap, wherein reflectivity can be ignored, as it is too small.

### Eleventh Embodiment

The present embodiment relates to analysis of transmittance and optical band gap (Eₒₚₜ) of YIZO thin films with different concentrations of yttrium wherein transmittance and optical band gap were measured by UV-Visible Spectrophotometer.

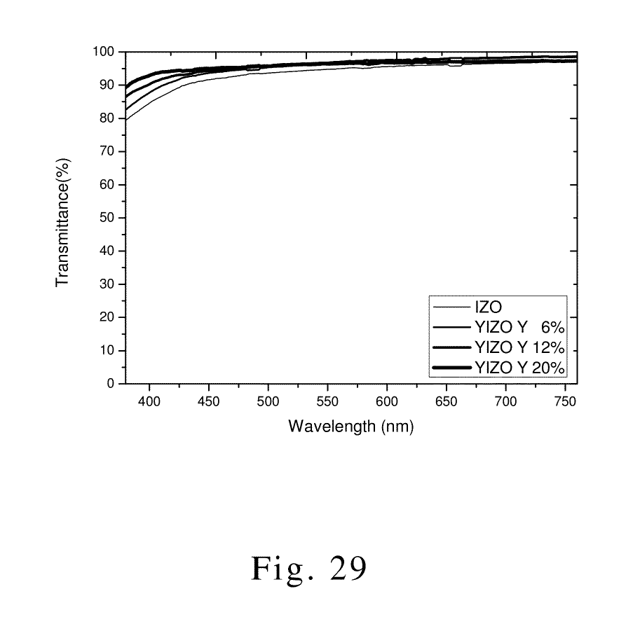

The present embodiment was to study optical characteristics of YIZO thin films with different concentrations of yttrium that had been sintered at 500° C. for 1 hour and the measurements of transmittance spectra were based on a blank SiO₂ substrate as the baseline. With reference to FIG. 29, when the doping ratio of yttrium is from 0 to 20% and in a wavelength range of 380 nm˜450 nm, the phenomenon that with increasing doping ratio of yttrium, transmittance increases and the absorption boundary shifts to shorter wavelength is obvious. When the doping ratios of yttrium of YIZO are 0%, 6%, 12% and 20%, the average transmittances of the visible light (in a range of 380 to 760 nm) are 94%, 95.9%, 96.0% and 96.1% respectively. The information of optical band gap and the average transmittances of the visible light with different doping concentrations of yttrium are shown in Table 5.

TABLE 5

| | | Average transmittances |
|---|---|---|
| Sample | Eₒₚₜ | (380~760 nm) |
| IZO Y0% | 3.1 eV | 94% |
| YIZO Y6% | 3.26 eV | 95.9% |
| YIZO Y12% | 3.38 eV | 96% |
| YIZO Y20% | 3.51 eV | 96.1% |

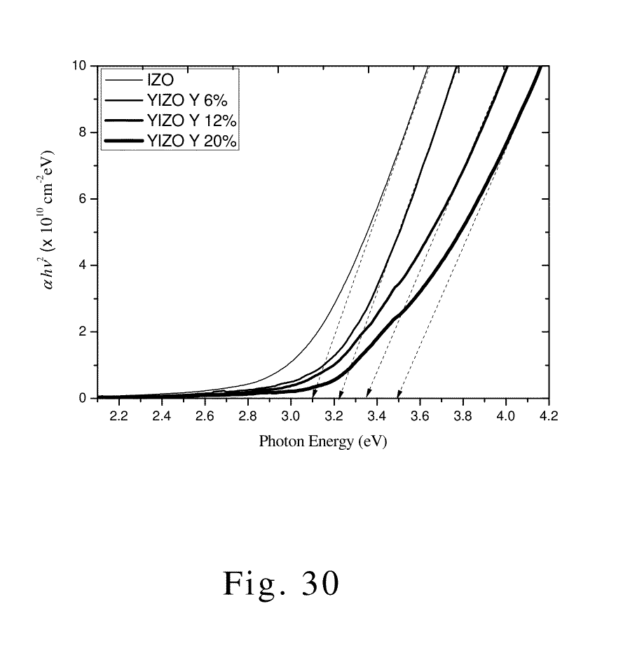

From the transmittances measured by transmittance spectra and from the previous tenth embodiment, because the reflectivity is too small, equation 3-9 can be simplified as equation 3-10 to calculate absorption coefficient and substitute the absorption coefficient into equation 3-11 to calculate optical band gap. With reference to FIG. 30, when the doping ratios of yttrium of YIZO are 0%, 6%, 12% and 20%, the optical band gaps are 3.1 eV, 3.26 eV, 3.38 eV and 3.51 eV respectively, which shows that with increasing doping ratio of yttrium, the optical band gap increases, with reference to Table 5.

The larger band gap is due to the yttrium oxide (Y₂O₃) doping into the indium zinc oxide system wherein the electronic band gap of Y₂O₃ is about 6 eV and the electronic band gap of indium zinc oxide is about 3.1 eV, and thus the band gap is larger when the doping ratio of yttrium is higher. As a result, more energy is needed for electrons to jump from valence band to conduction band, and thus the absorption boundary of transmittance spectra shifts to shorter wavelength and increases average transmittance of visible light.

### Twelfth Embodiment

The present embodiment relates to the analysis of XPS of YIZO thin films with different concentrations of yttrium.

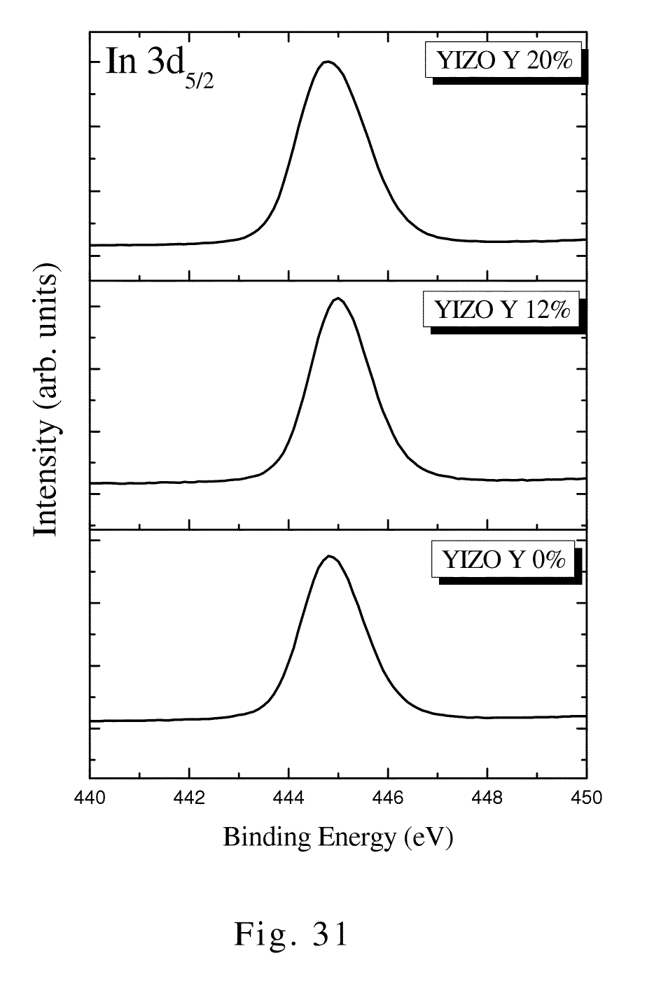

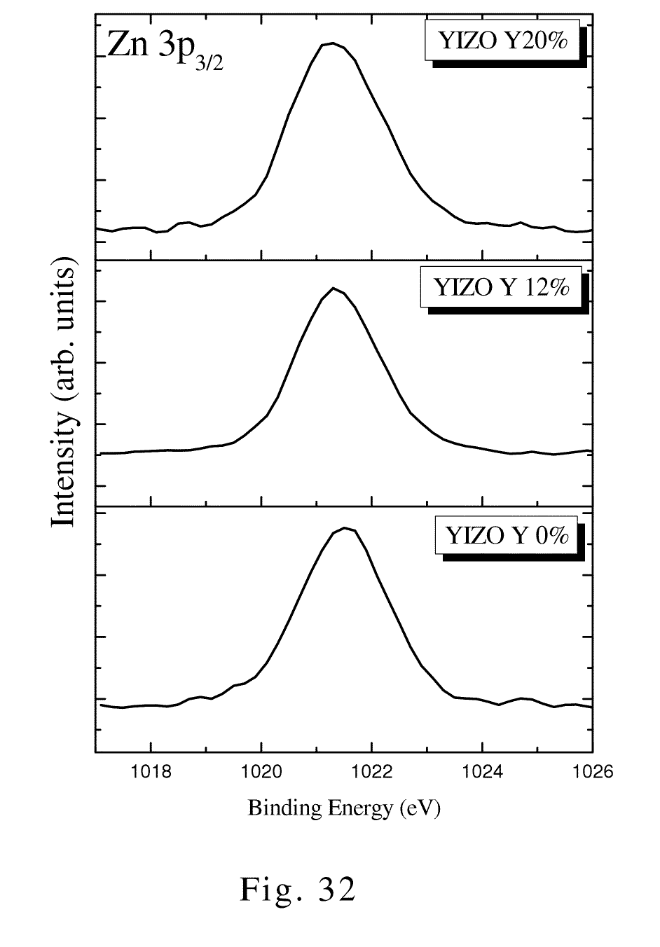

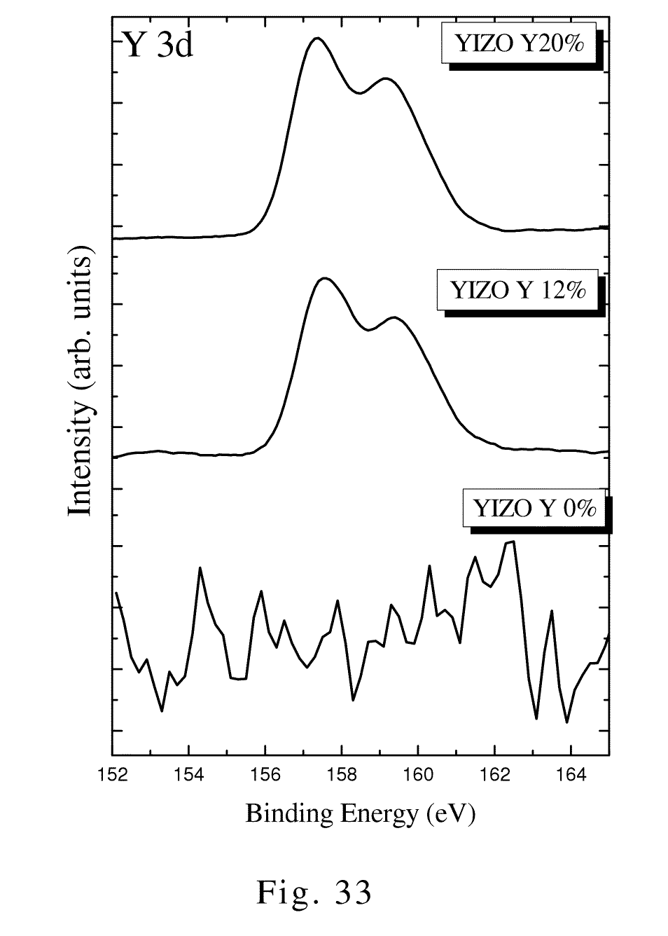

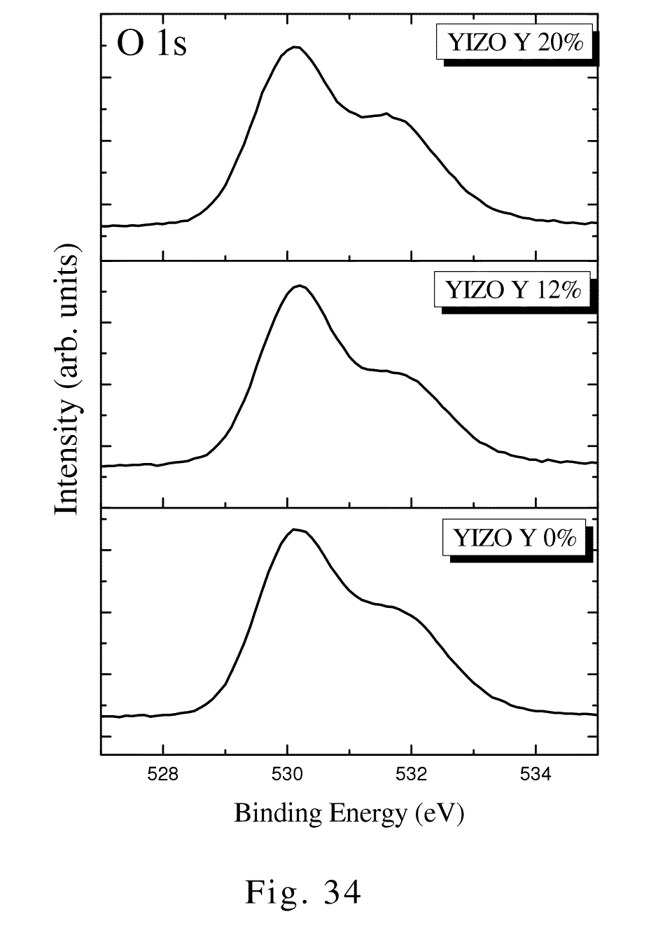

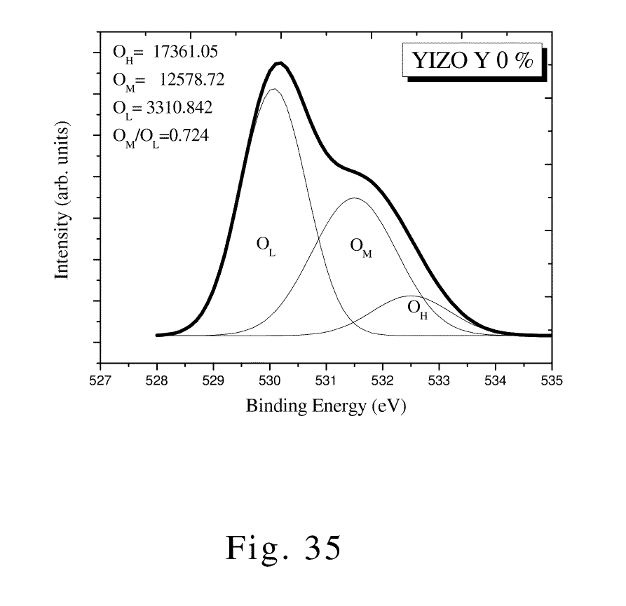

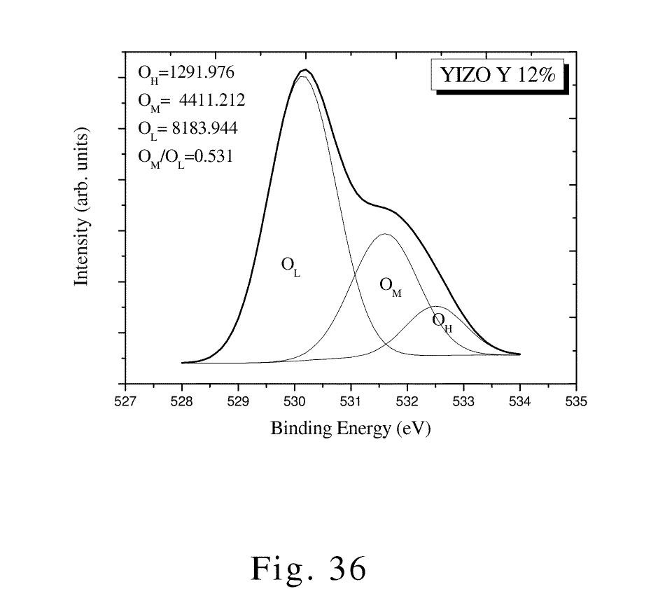

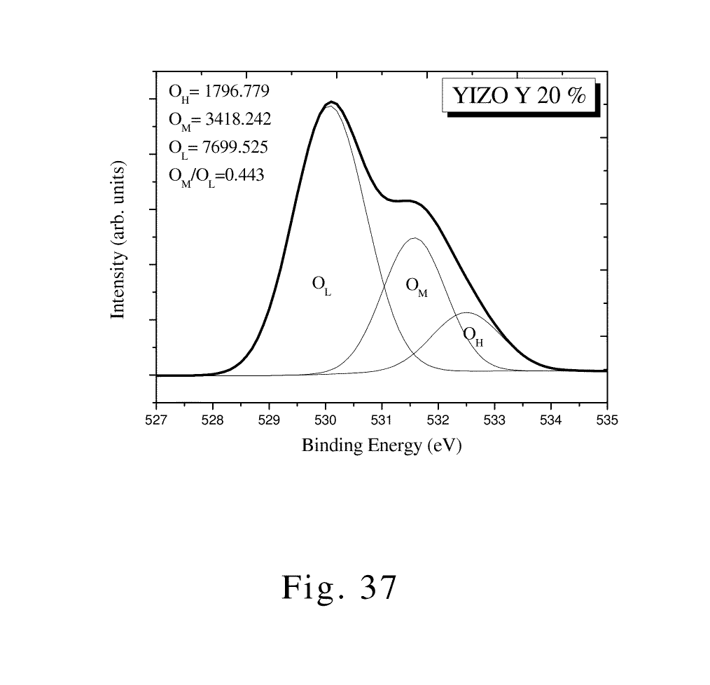

The XPS was used to study the bonding state of YIZO thin films with different concentrations of yttrium and to progress elemental analysis of indium, zinc, yttrium oxygen and carbon. Data of different samples obtained by XPS was based on the binding energy (B.E) of electrons in the 1s orbital of carbon of 284.5 eV, which was used as the correction reference. With reference to FIG. 34 to FIG. 37, each diagram is separated into up, middle and down part, which indicate the different doping amounts of yttrium of 20%, Y 12% and Y 0% respectively. The binding state of In 3d5/2 energy level is shown in FIG. 31 wherein the binding energy is about 444.6˜444.8 eV, which is the binding energy of core electrons of indium bonding to oxygen according to the publications. With increasing doping amount of yttrium, the binding energy slightly shifts to a lower energy. The binding state of Zn 3p3/2 energy level is shown in FIG. 32 wherein the binding energy is about 1020.9˜1021.8 eV, which is the binding energy of core electrons of zinc bonding to oxygen according to the publications. With increasing doping amount of yttrium, the binding energy shifts to a lower energy. With reference to FIG. 31 to FIG. 34, the electronegativity difference between yttrium (1.22) and oxygen (3.44) is 2.22, which is larger than the electronegativity difference between indium (1.78) and oxygen (1.66) and larger than the electronegativity difference between zinc (1.65) and oxygen. This indicates that yttrium electron cloud is obviously polarized toward the oxygen, thus resulting in a shorter distance between yttrium and oxygen and causing a phenomenon of deoxidization of the bonding between indium, zinc and oxygen. As a result, with increasing doping amount of yttrium, the binding energies of zinc 3p3/2 and indium 3d5/2 shift to lower energy. Moreover, standard electrode potential (SEP) can be used to explain the phenomenon as well, wherein the SEP of yttrium, indium and zinc are −2.67 V, −0.34 V and −0.76 V respectively. In YIZO system, the SEP of yttrium is the smallest, which indicates that yttrium is easy to lose electrons to form a steady state while bonding to oxygenthus affecting the bonding of indium to oxygen and the bonding of zinc to oxygen. The bonding state of Y 3d orbital is shown in FIG. 33. The spectrum shows two peaks wherein one of them is Y 3d3/2 and the B.E is about 158-159 eV, the other peak is Y 3d5/2 and the B.E of yttrium oxide bonding to oxygen is about 156-157 eV. The B.E increases with increasing doping amount of yttrium, and the much more amount of doping amount of yttrium indicates that yttrium incorporates into the indium zinc oxide system to bond to oxygen. The bonding state of O 1s orbital is shown in FIG. 33. to analyze the peaks of O 1s spectrum, as shown in FIG. 35 to FIG. 37. Peak fitting by Globle Gauss into three peaks, which are O_{L}, O_{M} and O_{H}, and the centers of O_{L}, O_{M} and O_{H}, are 530 eV, 531.6 eV and 532 eV respectively. O_{L} indicates the amount of bonding between indium, zinc and yttrium to oxygen, O_{M} indicates the amount of oxygen vacancies, and O_{H} indicates the amount of H₂O, CO₃, O₂ adsorbing to the surface. The major source of free carriers of oxide semiconductors is from the formation of oxygen vacancies, and thus the area under the curve (O_{M}/O_{L}) of O 1 s spectrum was analyzed. When the doping amounts of yttrium of YIZO thin film are 0%, 12% and 20%, O_{M}/O_{L} are 0.724, 0.531 and 0.443 respectively. O_{M}/O_{L} decreases with increasing doping amount of yttrium, which indicates that yttrium incorporates into the indium zinc oxide system and is able to suppress the formation of oxygen vacancies effectively and decrease carrier concentration. The result of the previous ninth embodiment shows that with increasing doping amount of yttrium, carrier concentration decreases from 10¹⁹ cm⁻³ to 10¹³ cm⁻³. The result of the present embodiment is in accordance with the result of the previous ninth embodiment, and the results prove that doping yttrium into IZO system, yttrium is able to capture oxygen effectively and reduces the formation of oxygen vacancies due to the large electronegativity difference between yttrium and oxygen or due to the low SEP of yttrium.

### CONCLUSION

From the embodiments mentioned above, solution processing was used to fabricate amorphous phase yttrium-doped indium zinc oxide and the amorphous phase yttrium-doped indium zinc oxide was used as the active layer of a TFT. Trivalent yttrium was doped into indium zinc oxide system and carrier concentration was suppressed by adjusting the doping ratio of yttrium. The electronegativities of yttrium, indium, zinc and oxygen are 1.22, 1.65, 1.78 and 3.44 respectively, and the electronegativity difference between yttrium and oxygen is larger than the electronegativity difference between indium and oxygen and is larger than the electronegativity difference between zinc and oxygen, which indicates that the extent of polarization of yttrium and oxygen is large, and thus yttrium is capable of binding oxygen strongly.

From the electrochemist point of view, the standard electrode potentials (SEP) of yttrium, indium and zinc are −2.65 V, −0.34 and −0.76 V respectively. Compared with the SEPs of the three elements, yttrium has a smallest SEP, which means that yttrium is easy to lose electrons to form a steady state while bonding to oxygen. From the result of Van der Pauw method, with increasing doping ratio of yttrium, carrier concentration decreases. With reference to FIG. 35 to FIG. 37 and from the analysis of O 1s spectrum measured by XPS, with increasing doping amount of yttrium, the area under curve (O_{M}/O_{L}) decreases, which indicates that trivalent yttrium in indium zinc oxide system is able to suppress the formation of oxygen vacancies and reduce carrier concentration. The result of XPS is in accordance with the result of carrier concentration measured by Van der Pauw method, as shown in Table 4. The results prove that adjusting the doping ratio of yttrium can control the carrier concentration.

Within the YIZO-TFTs with different doping ratios of yttrium, no switching characteristics are observed when the concentration of the active layer is too high. From the result mentioned above, TFT with better properties is with a 12%˜14% doping ratios of yttrium and the TFT exhibits carrier concentration in a range of 10¹⁴˜10¹⁵ cm⁻³, wherein the carrier concentration is applicable to TFTs. Moreover, TFT with the best properties is with a doping ratio of yttrium of 12%, the TFT exhibiting I_{on/off} ratio of 1.3×106, V_{T} of 3.68 V, the maximum of I_{DS} of 2.91×10-4, μₛₐₜ of 2.08 cm2/Vs and S.S. of 1.55 V/decade, with reference to Table 3. From the AFM diagrams of different doping ratios of yttrium, a smallest surface roughness is observed when the doping ratio of yttrium is 12%, with reference to FIG. 24 to FIG. 28. As shown in Table 3, the result of surface roughness is in accordance with N_{SS}^{max}, which indicates that the roughness of interface affects TFT properties seriously, and the result of AFM, shows that the smaller the surface roughness, the better the electrical characteristics.

As for the optical characteristics of Y₂O₃, the band gap of Y₂O₃ is about 6 eV and Y₂O₃ is doped into indium zinc oxide system, whose band gap is 3.1 eV, and thus doping Y₂O₃ will broaden the band gap. From the results of transmittance spectra, with increasing doping concentration of yttrium, the absorption boundary of materials shifts to shorter wavelength and average transmittances of the visible light increases, and the optical band gap increases from 3.1 eV to 3.51 eV, as shown in Table 5.

Even though numerous characteristics and advantages of the present invention have been set forth in the foregoing description, together with details of the structure and function of the invention, the disclosure is illustrative only, and changes may be made in detail. For example, The TFTs in the aforementioned embodiments do not have passivation layers to avoid water and oxygen, but different methods can be used to fabricate passivation layers to prevent the TFT from being unstable, and the passivation layers can be fabricated by such as depositing SiO₂, Si₃N₄ by vacuum PECVD, by spin coating PMMA, SU8, SiO2, photoresist or organic precursor, which are techniques to improve the stability of TFTs. The present invention is applicable to the aforementioned techniques of improving stability of TFTs, and the arrangement of parts is still within the principles of the invention.

Moreover, from the S.S value of the TFT, the smallest S.S of the present invention is about 1.55 V/decade. The S.S is adjusted to less than 1 V/decade in order to use a small voltage to make the TFT shift from off-state to on-state. Numerous modifications such as forming a rougher surface of SiO2 dielectric layer on the heavily doped boron p-Si substrate used in the above embodiments, substituting lightly doped p-Si substrate to improve TFT properties and increase the on/off ratio of device are still within the spirit and scope of the present invention. Besides, changing different reagents to fabricate different properties of YIZO thin films in order to improve the TFT property is also within the spirit and scope of the present invention.

What is claimed is:

1. A thin film transistor device comprising:
a gate substrate;
a dielectric layer formed on one surface of the gate substrate;
an active layer composed of yttrium-doped indium zinc oxide and formed on the dielectric layer to be defined as a region, wherein the doping ratio of yttrium is 12% to 14%;
a source electrode forming an Ohmic contact with the active layer; and
a drain electrode forming an Ohmic contact with the active layer.

2. The thin film transistor device according to claim 1, wherein the gate substrate is composed of silicon or heavily doped boron silicon; the dielectric layer is composed of silicon dioxide or silicon nitride.

3. The thin film transistor device according to claim 2, wherein the thickness of the dielectric layer is 80 nm to 300 nm.

4. The thin film transistor device according to claim 3, wherein the dielectric layer is selected from the group consisting of: a 300 nm thick SiO₂ layer, a 300 nm thick SiO₂ layer and a 300 nm thick Si₃N₄ layer.

5. The thin film transistor device according to claim 4, wherein the molarity of indium of the active layer and the molarity of zinc of the active layer are the same.

6. A method for making a thin film transistor device comprising steps of:
preparing a gate electrode;
washing the gate electrode to form a clean surface without oil or organic residual;
forming a dielectric layer on the clean surface of the gate electrode;
forming an active layer on the dielectric layer, wherein the active layer is composed of yttrium-doped indium zinc oxide and the doping ratio of yttrium is 12% to 14%;
forming a source electrode and a drain electrode on the active layer, wherein the source electrode and the drain electrode form an Ohmic contact with the active layer; and
defining an area and an unwanted part of the active layer, and removing the unwanted part of the active layer to define the active layer as a region.

7. The method for making a thin film transistor device according to claim 6, wherein the dielectric layer is formed by growing a 300 nm thick SiO₂ layer with wet oxidation carried out in a horizontal tube furnace by growing an 80 nm thick SiO₂ layer with dry oxidation carried out in a horizontal tube furnace, or by growing a 300 nm thick Si₃N₄ layer by PECVD at room temperature.

8. The method for making a thin film transistor device according to claim 7, wherein the dielectric layer is formed by growing an 80 nm thick SiO₂ layer with dry oxidation carried out in a horizontal tube furnace; wherein the gate electrode is composed of heavily doped boron silicon.

9. The method for making a thin film transistor device according to claim 8, wherein the active layer is fabricated by non-vacuum sol-gel process wherein the sintering temperature is 500° C. and the active layer is sintered under atmosphere for one hour.

10. The method for making a thin film transistor device according to claim 9, wherein exposure lithography is used to define an area of the active layer and an unwanted part of the active layer.
